(19) United States
(12) Patent Application Publication
(10) Pub. No.: US 2025/0293903 A1
(43) Pub. Date: Sep. 18, 2025

(54) Systems and Methods for Low Latency Transmission and Digital Link Adaptation

(71) Applicant: TeraSignal LLC, Newport Coast, CA (US)

(72) Inventors: Wim Cops, Newport Coast, CA (US); Armond Hairapetian, Newport Coast, CA (US)

(73) Assignee: TeraSignal LLC, Newport Coast, CA (US)

(21) Appl. No.: 19/082,016

(22) Filed: Mar. 17, 2025

Related U.S. Application Data
(60) Provisional application No. 63/566,153, filed on Mar. 15, 2024.
(60) Provisional application No. 63/566,836, filed on Mar. 18, 2024.

(51) Int. Cl. H04L 25/03; H03F 3/195; H04L 25/06

(52) U.S. Cl. CPC H04L 25/03885; H03F 3/195; H04L 25/062

(57) ABSTRACT

Systems and methods for intelligent re-drivers capable of link monitoring and link training in accordance with embodiments of the invention are illustrated. A re-driver in accordance with a first embodiment includes a programmable linear equalizer capable of equalizing a transmitted analog signal to generate an equalized signal, and a variable gain amplifier capable of amplifying the equalized signal to produce an amplified signal. The re-driver further includes a line driver capable of generating an output signal based upon the amplified signal, and digital link adaptation circuitry that is capable of sampling the amplified signal to produce a sampled signal, generating programming parameters for the programmable linear equalizer based upon the sampled signal, and programming the programmable linear equalizer.

### CROSS-REFERENCE TO RELATED APPLICATIONS

The current application claims the benefit of and priority under 35 U.S.C. § 119(e) to U.S. Provisional Patent Application No. 63/566,153 entitled “High-speed Interconnects and Methods for Low Latency Transmission Using Intelligent Re-drivers Capable of Digital Link Adaptation” filed Mar. 15, 2024, and U.S. Provisional Patent Application No. 63/566,836 entitled “High-speed Interconnects and Methods for Low Latency Transmission Using Intelligent Re-drivers Capable of Digital Link Adaptation” filed Mar. 18, 2024, the disclosures of which are hereby incorporated by reference in their entirety for all purposes.

### FIELD OF THE INVENTION

The present invention generally relates to high-speed interconnects, and, more specifically, intelligent re-drivers capable of link adaptation.

### BACKGROUND

High-speed interconnects (HSIs) are communication links that can transmit data at speeds of several gigabits per second. These interconnects are commonly used in high-speed data communication applications within data centers, telecommunication systems, and consumer electronics. HSIs can allow for the fast and efficient transfer of large amounts of data over short and long distances. However, transmission lines typically have signal integrity problems, even with perfect impedance matching. Accordingly, HSIs typically experience distortion and inter-symbol interference (ISI). In order to achieve high data rates, HSIs are typically designed to mitigate the effects of signal distortion and ISI.

A common approach to address signal distortion is to use extension devices that can regenerate and/or amplify transmitted signals. Extension devices typically work by receiving signals that may have been weakened in transmission, amplifying them, and retransmitting them to the next segment of the communication channel. This process of retransmission can help compensate for the signal loss and restore the strength of transmission, effectively extending the reach of the communication link. Examples of extension devices that can extend the range of HSIs by boosting transmissions and mitigate effects of distortion and ISI include re-timers and re-drivers. A re-timer is a mixed signal analog/digital device that is protocol-aware and has the ability to fully recover transmitted data, extract the embedded clock, and retransmit a fresh copy of the data that is cleaner and more reliable. Re-timers can be used in communication systems to regenerate signals that have been attenuated or distorted due to transmission over long distances and can help to improve the overall performance of a communication link by reducing errors and improving the signal-to-noise ratio.

A re-driver is a mostly analog reach extension device designed to boost the high-frequency portions of a transmitted signal to counteract frequency-dependent attenuation. Re-drivers generally provide the ability to amplify the signal, which can help to compensate for signal distortion and attenuation, which can occur due to a variety of factors such as (but not limited to) transmission over long distances, impedance mismatches, and/or other signal impairments.

Re-timers, such as the re-timer illustrated in FIG. 1, typically include a continuous time linear equalizer (CTLE) and an amplifier for wideband gain stages that may also be found in a re-driver. Re-timers further include a clock and data recovery (CDR) circuit that is capable of extracting the clock and data signals from the transmitted signals. The CDR gives re-timers the ability to regenerate a new copy of the transmitted signal. Re-timers can also include a decision feedback equalizer (DFE) that processes signal reflections by the channel, and a receive and/or transmit (Tx) finite impulse response (FIR) driver. Finite state machines (FSMs) and/or a microcontroller typically manage the automatic adaptation of the CTLE, wideband gain, DFE, and FIR driver. In the illustrated example, these components also implement a Peripheral Component Interface Express (PCIe) link training and status state machine (LTSSM). In the context of PCIe, re-timers can actively participate in the PCIe protocol as the PCIe protocol provides the details necessary for the re-timers to participate during different stages of transmission.

Re-drivers, on the other hand, are typically unaware of the underlying communication protocol, and often require monitoring and tuning such that the signals can be transmitted smoothly. A conventional re-driver is illustrated in FIG. 2 and includes a data path having a CTLE, an amplifier for a wideband gain stage, and a linear driver. In addition, re-drivers often have input loss-of-signal threshold and output receiver (Rx) detection capability. If anything goes wrong during transmission, it may be difficult to pinpoint whether the problem is caused by components before the re-driver or after it, since the re-driver's role in link formation is undefined and unknown to its link partners. Furthermore, re-timers are often preferred because they can reset the jitter and insertion loss budgets within a communication link whereas re-drivers do not. With the CDR unit, re-timers can fully recover the data stream and retransmit it on a clean clock.

### SUMMARY OF INVENTION

Systems and methods for intelligent re-drivers capable of link monitoring and link training in accordance with embodiments of the invention are illustrated. A re-driver in accordance with a first embodiment includes a programmable linear equalizer capable of equalizing a transmitted analog signal to generate an equalized signal, and a variable gain amplifier capable of amplifying the equalized signal to produce an amplified signal. The re-driver further includes a line driver capable of generating an output signal based upon the amplified signal, and digital link adaptation circuitry that is capable of sampling the amplified signal to produce a sampled signal, generating programming parameters for the programmable linear equalizer based upon the sampled signal, and programming the programmable linear equalizer.

A re-driver in accordance with a second embodiment includes the features of the first embodiment, wherein the variable gain amplifier is a programmable variable gain amplifier, and the digital link adaptation circuitry is further capable of generating programming parameters for the programmable variable gain amplifier based upon the sampled signal, and programming the programmable variable gain amplifier.

A re-driver in accordance with a third embodiment includes the features of the first and second embodiments, wherein the digital link adaptation circuitry is further capable of generating programming parameters for a transmitter based upon the sampled signal, and sending the programming parameters to the transmitter.

A re-driver in accordance with a fourth embodiment includes the features of the first through third embodiments, wherein the digital link adaptation circuitry is further capable of measuring a channel impulse response when the transmitted analog signal is a pulse.

A re-driver in accordance with a fifth embodiment includes the features of the fourth embodiment, wherein the digital link adaptation circuitry is further capable of characterizing the channel by taking the derivative of the measured channel impulse response.

A re-driver in accordance with a sixth embodiment includes the features of the fourth and fifth embodiments, wherein the duration of the pulse is greater than a time required for transients caused by reflections of the pulse within the channel to have settled.

A re-driver in accordance with a seventh embodiment includes the features of the third through sixth embodiments, wherein the programming parameters for the transmitter are based upon the characterization of the channel.

A re-driver in accordance with an eighth embodiment includes the features of the third through seventh embodiments, wherein the transmitter includes a feed-forward equalizer (FFE) having a plurality of taps and the programming parameters configure the taps of the FFE.

A re-driver in accordance with a ninth embodiment includes the features of the eighth embodiment, wherein the duration of the pulse is greater than a time required for transients caused by reflections of the pulse within the channel to have settled, and the number of the plurality of taps of the FFE corresponds to a duration of time that is equal to or greater than the time required for transients caused by reflections of the pulse within the channel to have settled.

A re-driver in accordance with a tenth embodiment includes the features of the third through ninth embodiments, wherein the programming parameters for a transmitter further include programming parameters that the transmitter can utilize to obtain local Continuous Time Linear Equalization (CTLE) coefficients.

A re-driver in accordance with an eleventh embodiment includes the features of the first through tenth embodiments, wherein the programmable linear equalizer, the variable gain amplifier, the line driver, and the digital link adaptation circuitry are formed on a single integrated circuit.

A re-driver in accordance with a twelfth embodiment includes the features of the first through eleventh embodiments, wherein the digital link adaptation circuitry includes an analog to digital converter, and a microcontroller unit (MCU).

A re-driver in accordance with a thirteenth embodiment includes the features of the first through twelfth embodiments, wherein the programmable linear equalizer, the variable gain amplifier, and the line driver are formed on a first integrated circuit, and at least one of the analog to digital converter and the microcontroller unit are formed on a second integrated circuit capable of receiving signals from the first integrated circuit.

A re-driver in accordance with a fourteenth embodiment includes the features of the twelfth embodiment, wherein the programmable linear equalizer, the variable gain amplifier, and the line driver are formed on a first integrated circuit, and both the analog to digital converter and the microcontroller unit are formed on a second integrated circuit capable of receiving signals from the first integrated circuit.

A re-driver in accordance with a fifteenth embodiment includes the features of the twelfth through fourteenth embodiments, wherein the analog to digital converter is a 12-bit analog to digital converter.

A re-driver in accordance with a sixteenth embodiment includes the features of the twelfth through fifteenth embodiments, wherein the digital link adaptation circuitry is further capable of recovering a sampling clock signal from the sampled signal.

A re-driver in accordance with a seventeenth embodiment includes the features of the sixteenth embodiment, wherein the digital link adaptation circuitry includes a clock recovery unit configured to receive the sampled signal, a phase interpolator configured to receive an input signal from the clock recovery unit, and a clock divider configured to receive an input from the phase interpolator and output the sampling clock signal.

A re-driver in accordance with a eighteenth embodiment includes the features of the seventeenth embodiment, wherein the clock recovery unit includes a voltage controlled oscillator (VCO), a phase lock loop (PLL), and control circuitry comprising a control register, where the control circuitry is configured to control the control register based upon at least control signals received from the MCU, where the MCU is configured to receive the sampling clock signal from the clock divider and output control signals that are provided to the clock recovery unit, where the control signals are capable of being used by the clock recovery unit to control the frequency of the VCO.

A re-driver in accordance with a nineteenth embodiment includes the features of the eighteenth embodiment, wherein the phase lock loop includes a phase detector, and a filter.

A re-driver in accordance with a twentieth embodiment includes the features of the eighteenth and nineteenth embodiments, wherein the MCU is connected to a crystal oscillator capable of generating a clock signal, and the MCU is configured to obtain a reference signal using the clock signal, and control the frequency of the VCO based upon the reference signal.

A re-driver in accordance with a twenty first embodiment includes the features of the eighteenth through twentieth embodiments, wherein the MCU is capable of implementing a state a machine for generating control signals for the VCO.

A re-driver in accordance with a twenty second embodiment includes the features of the twenty first embodiment, wherein the state machine causes the MCU to generate a first control signal that instructs the clock recovery unit to increase the frequency of the VCO when the MCU determines that the frequency of the oscillator is less than the target frequency by more than a first acceptable margin, and generate a second control signal that instructs the clock recovery unit to decrease the frequency of the VCO when the MCU determines that the frequency of the oscillator is greater than the target frequency by more than a second acceptable margin.

A re-driver in accordance with a twenty third embodiment includes the features of the twenty first and twenty second embodiments, wherein the state machine causes the MCU to generate a third control signal that instructs the clock recovery unit to maintain the frequency of the VCO when the MCU determines that the frequency of the oscillator is within an acceptable margin of the target frequency.

A re-driver in accordance with a twenty fourth embodiment includes the features of the sixteenth through twenty third embodiments, wherein the re-driver is capable of varying the sampling phase of the sampling clock signal to perform a scan.

A re-driver in accordance with a twenty fifth embodiment includes the features of the first through twenty fourth embodiments, wherein the digital link adaptation circuitry is further capable of receiving, via an input, a sampling clock signal from a synchronous clock source or a synchronous neighboring channel.

A re-driver in accordance with a twenty sixth embodiment includes the features of the first through twenty fifth embodiments, wherein the digital link adaptation circuitry is configurable to obtain a sampling clock signal by recovering the sampling clock signal from the sampled signal, or receiving, via an input, the sampling clock signal from a synchronous clock source or a synchronous neighboring channel.

A re-driver in accordance with a twenty seventh embodiment includes the features of the first through twenty sixth embodiments, further including a skew adjustor.

A re-driver in accordance with a twenty eighth embodiment includes the features of the first through twenty seventh embodiments, further including a content management interoperability services (CMIS) interface capable of facilitating communication for link training.

A re-driver in accordance with a twenty nineth embodiment includes the features of the first through twenty eighth embodiments, wherein the digital link adaptation circuitry sets feed-forward equalization coefficients for the transmitter of the re-driver.

A re-driver in accordance with a thirtieth embodiment includes the features of the first through twenty nineth embodiments, further including outputting digital eye diagram from the digital link adaptation circuitry to a digital eye monitor.

A re-driver in accordance with a thirty first embodiment includes the features of the first through thirtieth embodiments, wherein the digital link adaptation circuitry comprises a 12-bit analog-to-digital converter.

A re-driver in accordance with a thirty second embodiment includes the features of the first through thirty first embodiments, wherein the programming parameters removes inter-symbol interference in a communication channel.

A re-driver in accordance with a thirty third embodiment includes the features of the first through thirty second embodiments, wherein the variable gain amplifier, and the line driver form a signal path.

A re-driver in accordance with a thirty fourth embodiment includes the features of the first through thirty third embodiments, wherein the signal path also includes additional analog components and optionally includes additional analog components between the programmable linear equalizer and the variable gain amplifier and/or between the variable gain amplifier and the line driver.

A re-driver in accordance with a thirty fifth embodiment includes the features of the first through thirty fourth embodiments, wherein the programmable linear equalizer is a continuous time linear equalizer.

A re-driver in accordance with a thirty sixth embodiment includes the features of the first through thirty fifth embodiments, wherein the re-driver is capable of being configured in a link training mode in which a transmitter transmits at least one pulse via the channel that can be utilized by the re-driver to perform channel characterization, and a re-driver mode in which the transmitter transmits data via the channel.

A re-driver in accordance with a thirty seventh embodiment includes the features of the first through thirty sixth embodiments, wherein the re-driver is configured to communicate with the transmitter via a content management interoperability services (CMIS) interface.

A method for performing link training of a high speed serial link in accordance with a thirty eighth embodiment includes sampling, at an extension device receiver, an analog signal transmitted by a transmitter via a channel using an analog-to-digital converter, where the transmitted analog signal is a pulse, and characterizing, at the extension device, the channel based upon the sampled analog signal. The method further includes generating, at the extension device, parameters that are capable of being used by the transmitter to program an equalizer, and transmitting, by the extension device, the generated parameters to the transmitter.

A method for performing link training of a high speed serial link in accordance with a thirty ninth embodiment includes the features of the thirty eighth embodiment, wherein the duration of the pulse is greater than a time required for transients caused by reflections of the pulse within the channel to have settled.

A method for performing link training of a high speed serial link in accordance with a fortieth embodiment includes the features of the thirty eighth and thirty ninth embodiments, further including measuring a channel impulse response based upon the sampled analog signal, and characterizing the channel based upon the sampled analog signal comprises taking a derivative of the measured channel impulse response.

A method for performing link training of a high speed serial link in accordance with a forty first embodiment includes the features of the thirty eighth through fortieth embodiments, wherein the generated parameters are capable of being used by the transmitter to program an equalizer that is a Feed Forward Equalizer (FFE) having a plurality of taps, where the number of the plurality of taps of the FFE corresponds to a duration of time that is equal to or greater than the time required for transients caused by reflections of the pulse within the channel to have settled.

A method for performing link training of a high speed serial link in accordance with a forty second embodiment includes the features of the thirty eighth through forty first embodiments, wherein the extension device is a re-driver comprising a programmable linear equalizer, and the method further includes generating programming parameters for the programmable linear equalizer based upon the sampled analog signal, and programming the programmable linear equalizer based upon the generated programming parameters.

A method for performing link training of a high speed serial link in accordance with a forty third embodiment includes the features of the thirty eighth through forty second embodiments, wherein the extension device is a re-timer.

A re-driver capable of receiving a transmitted analog signal via a channel in accordance with a forty fourth embodiment includes a programmable linear equalizer capable of equalizing the transmitted analog signal to generate an equalized signal, a variable gain amplifier capable of amplifying the equalized signal to produce an amplified signal, wherein the variable gain amplifier is a programmable variable gain amplifier, a line driver capable of generating an output signal based upon the amplified signal, and digital link adaptation circuitry including an analog to digital converter, a microcontroller unit, wherein the digital link adaptation circuitry is capable of sampling the amplified signal to produce a sampled signal when the transmitted analog signal is a pulse, measuring a channel impulse response, characterizing the channel by taking the derivative of the measured channel impulse response having a duration that is greater than a time required for transients caused by reflections of the pulse within the channel to have settled, generating programming parameters for the programmable linear equalizer based upon the characterization of the channel, programming the programmable linear equalizer using the programming parameters for the programmable linear equalizer, generating programming parameters for the programmable variable gain amplifier based upon the characterization of the channel, programming the programmable variable gain amplifier using the programming parameters for the programmable variable gain amplifier, generating programming parameters for a transmitter that are capable of being used by the transmitter to program a plurality of taps of a feed forward equalizer based upon the characterization of the channel, and transmitting the programming parameters for the transmitter to the transmitter, wherein the programmable linear equalizer, the variable gain amplifier, and the line driver are formed on a first integrated circuit, wherein at least one of the analog to digital converter and the microcontroller unit are formed on a second integrated circuit capable of receiving signals from the first integrated circuit, and wherein the microcontroller unit is configured to receive a clock signal from a crystal oscillator.

A re-driver capable of receiving a transmitted analog signal via a channel in accordance with a forty fifth embodiment includes the features of the forty fourth embodiment, wherein the digital link adaptation circuitry includes a clock recovery unit configured to receive the sampled signal, where the clock recovery unit further includes a voltage controlled oscillator (VCO), a phase lock loop (PLL), and control circuitry comprising a control register, where the control circuitry is configured to control the control register based upon at least control signals received from the MCU. The re-driver further includes a phase interpolator configured to receive an input signal from the clock recovery unit, and a clock divider configured to receive an input from the phase interpolator and output the sampling clock signal, wherein the MCU is configured to receive the sampling clock signal from the clock divider and output control signals that are provided to the clock recovery unit, where the control signals are capable of being used by the clock recovery unit to control the frequency of the VCO, wherein the MCU is configured to obtain a reference signal using the clock signal, and control the frequency of the VCO based upon the reference signal.

A re-driver capable of receiving a transmitted analog signal via a channel in accordance with a forty sixth embodiment includes the features of the first through thirty seventh, and forty fourth and forty fifth embodiments, wherein the channel is an optical communication channel.

A re-driver capable of receiving a transmitted analog signal via a channel in accordance with a forty seventh embodiment includes the features of the first through thirty seventh, and forty fourth through forty sixth embodiments, performing any of the methods of the thirty eighth through forty third embodiments.

A method for performing link training of a high speed serial link in accordance with a forty eighth embodiment includes the features of the thirty eighth through forty third embodiments performed by re-drivers including the features of the first through thirty seventh, and forty fourth through forty sixth embodiments.

A high-speed interconnect in accordance with a forty ninth embodiment includes a transmitter capable of transmitting an analog signal via a channel, and a re-driver including the features of the first through thirty seventh, and forty fourth through forty sixth embodiments.

A high-speed interconnect in accordance with a fiftieth embodiment includes a transmitter capable of transmitting an analog signal via a channel, a re-driver including the features of the first through thirty seventh, and forty fourth through forty sixth embodiments, wherein the high-speed interconnect performs the methods of thirty eighth through forty third embodiments.

A high-speed interconnect in accordance with a fifty first embodiment includes a transmitter capable of transmitting an analog signal via a channel, a re-driver capable of receiving the transmitted analog signal via the channel, where the re-driver includes a programmable linear equalizer capable of equalizing a transmitted analog signal to generate an equalized signal, a variable gain amplifier capable of amplifying the equalized signal to produce an amplified signal, a line driver capable of generating an output signal based upon the amplified signal; and digital link adaptation circuitry capable of sampling the amplified signal to produce a sampled signal, generating programming parameters for the programmable linear equalizer based upon the sampled signal, and programming the programmable linear equalizer.

A high-speed interconnect in accordance with a fifty second embodiment includes the features of the fifty first embodiment, wherein the variable gain amplifier is a programmable variable gain amplifier, and the digital link adaptation circuitry is further capable of generating programming parameters for the programmable variable gain amplifier based upon the sampled signal, and programming the programmable variable gain amplifier.

A high-speed interconnect in accordance with a fifty third embodiment includes the features of the fifty first and fifty second embodiments, wherein the digital link adaptation circuitry is further capable of generating programming parameters for the transmitter based upon the sampled signal, and sending the programming parameters to the transmitter.

A high-speed interconnect in accordance with a fifty fourth embodiment includes the features of the fifty first through fifty third embodiments, wherein the digital link adaptation circuitry is further capable of measuring a channel impulse response when the transmitted analog signal is a pulse.

A high-speed interconnect in accordance with a fifty fifth embodiment includes the features of the fifty fourth embodiment, wherein the digital link adaptation circuitry is further capable of characterizing the channel by taking the derivative of the measured channel impulse response.

A high-speed interconnect in accordance with a fifty sixty embodiment includes the features of the fifty fourth and fifty fifth embodiments, wherein the duration of the pulse is greater than a time required for transients caused by reflections of the pulse within the channel to have settled.

A high-speed interconnect in accordance with a fifty seventh embodiment includes the features of the fifty fourth through fifty sixth embodiments, wherein the programming parameters for the transmitter are based upon the characterization of the channel.

A high-speed interconnect in accordance with a fifty eighth embodiment includes the features of the fifty fourth through fifty seventh embodiments, wherein the transmitter comprises a feed-forward equalizer (FFE) having a plurality of taps and the programming parameters configure the taps of the FFE.

A high-speed interconnect in accordance with a fifty ninth embodiment includes the features of the fifty eighth embodiment, wherein the duration of the pulse is greater than a time required for transients caused by reflections of the pulse within the channel to have settled, and the number of the plurality of taps of the FFE corresponds to a duration of time that is equal to or greater than the time required for transients caused by reflections of the pulse within the channel to have settled.

A high-speed interconnect in accordance with a sixtieth embodiment includes the features of the fifty second through fifty ninth embodiments, wherein the programmable linear equalizer, the variable gain amplifier, the line driver, and the digital link adaptation circuitry are formed on a single integrated circuit.

A high-speed interconnect in accordance with a sixth first embodiment includes the features of the fifty second through sixtieth embodiments, wherein the digital link adaptation circuitry includes an analog to digital converter (ADC), and a microcontroller unit (MCU).

A high-speed interconnect in accordance with a sixty second embodiment includes the features of the sixth first embodiment, wherein the programmable linear equalizer, the variable gain amplifier, and the line driver are formed on a first integrated circuit, and at least one of the analog to digital converter and the microcontroller unit are formed on a second integrated circuit capable of receiving signals from the first integrated circuit.

A high-speed interconnect in accordance with a sixty third embodiment includes the features of the sixty first embodiment, wherein the programmable linear equalizer, the variable gain amplifier, and the line driver are formed on a first integrated circuit, and both the analog to digital converter and the microcontroller unit are formed on a second integrated circuit capable of receiving signals from the first integrated circuit.

A high-speed interconnect in accordance with a sixty fourth embodiment includes the features of the sixty first through sixty third embodiments, wherein the ADC is capable of digitizing the transmitted analog signal, and the MCU is capable of analyzing the digitized signal.

A high-speed interconnect in accordance with a sixty fifth embodiment includes the features of the sixty first through sixty fourth embodiments, wherein the MCU is further capable of analyze the digitized signal to extract parameters that can be used to adjust the various analog components used in the transmission of the signal in a manner that compensates for channel impairments.

A high-speed interconnect in accordance with a sixty sixth embodiment includes the features of the sixty first through sixty fifth embodiments, wherein the ADC is capable of sampling the channel at a rate that is slower than a symbol rate of the channel when the transmitter transmits data.

A high-speed interconnect in accordance with a sixty seventh embodiment includes the features of the sixty first through sixty sixth embodiments, wherein the ADC is capable of oversampling transients caused by reflections of a pulse transmitted by the transmitter during a link training phase.

A high-speed interconnect in accordance with a sixty eighth embodiment includes the features of the sixty first through sixty seventh embodiments, wherein the analog to digital converter is a 12-bit analog to digital converter.

A high-speed interconnect in accordance with a sixty nineth embodiment includes the features of the sixty first through sixty eighth embodiments, wherein digital link adaptation circuitry is further capable of recovering a sampling clock signal from the sampled signal.

A high-speed interconnect in accordance with a seventieth embodiment includes the features of the sixty nineth embodiment, wherein the digital link adaptation circuitry includes a clock recovery unit configured to receive the sampled signal, a phase interpolator configured to receive an input signal from the clock recovery unit, and a clock divider configured to receive an input from the phase interpolator and output the sampling clock signal.

A high-speed interconnect in accordance with a seventy first embodiment includes the features of the seventieth embodiment, wherein the clock recovery unit includes a voltage controlled oscillator (VCO), a phase lock loop (PLL), and control circuitry comprising a control register, where the control circuitry is configured to control the control register based upon at least control signals received from the MCU, the MCU is configured to receive the sampling clock signal from the clock divider and output control signals that are provided to the clock recovery unit, where the control signals are capable of being used by the clock recovery unit to control the frequency of the VCO.

A high-speed interconnect in accordance with a seventy second embodiment includes the features of the seventy first embodiment, wherein the phase lock loop includes a phase detector, and a filter.

A high-speed interconnect in accordance with a seventy third embodiment includes the features of the seventieth and seventy first embodiments, wherein the MCU is connected to a crystal oscillator capable of generating a clock signal, the MCU is configured to obtain a reference signal using the clock signal, and control the frequency of the VCO based upon the reference signal.

A high-speed interconnect in accordance with a seventy fourth embodiment includes the features of the seventy first through seventy third embodiments, wherein the MCU is capable of implementing a state a machine for generating control signals for the VCO.

A high-speed interconnect in accordance with a seventy fifth embodiment includes the features of the seventy fourth embodiment, wherein the state machine causes the MCU to generate a first control signal that instructs the clock recovery unit to increase the frequency of the VCO when the MCU determines that the frequency of the oscillator is less than the target frequency by more than a first acceptable margin; and generate a second control signal that instructs the clock recovery unit to decrease the frequency of the VCO when the MCU determines that the frequency of the oscillator is greater than the target frequency by more than a second acceptable margin.

A high-speed interconnect in accordance with a seventy sixth embodiment includes the features of the seventy fourth and seventy fifth embodiments, wherein the state machine causes the MCU to generate a third control signal that instructs the clock recovery unit to maintain the frequency of the VCO when the MCU determines that the frequency of the oscillator is within an acceptable margin of the target frequency.

A high-speed interconnect in accordance with a seventy seventh embodiment includes the features of the fifty first through seventy sixth embodiments, wherein the re- driver is capable of varying the sampling phase of the sampling clock signal to perform a scan.

A high-speed interconnect in accordance with a seventy eighth embodiment includes the features of the fifty first through seventy seventh embodiments, wherein the digital link adaptation circuitry is further capable of receiving, via an input, a sampling clock signal from a synchronous clock source or a synchronous neighboring channel.

A high-speed interconnect in accordance with a seventy nineth embodiment includes the features of the fifty first through seventy eighth embodiments, wherein digital link adaptation circuitry is configurable to obtain a sampling clock signal by recovering the sampling clock signal from the sampled signal; or receiving, via an input, the sampling clock signal from a synchronous clock source or a synchronous neighboring channel.

A high-speed interconnect in accordance with an eightieth embodiment includes the features of the fifty first through seventy nineth embodiments, further including a skew adjustor.

A high-speed interconnect in accordance with an eighty first embodiment includes the features of the fifty first through eightieth embodiments, further including a content management interoperability services (CMIS) interface capable of facilitating communication for link training.

A high-speed interconnect in accordance with an eighty second embodiment includes the features of the fifty first through eighty first embodiments, wherein the digital link adaptation circuitry sets feed-forward equalization coefficients for the transmitter of the re-driver.

A high-speed interconnect in accordance with an eighty third embodiment includes the features of the fifty first through eighty second embodiments, further including outputting digital eye diagram from the digital link adaptation circuitry to a digital eye monitor.

A high-speed interconnect in accordance with an eighty fourth embodiment includes the features of the fifty first through eighty third embodiments, wherein the digital link adaptation circuitry comprises a 12-bit analog-to-digital converter.

A high-speed interconnect in accordance with an eighty fifth embodiment includes the features of the fifty first through eighty fourth embodiments, wherein the programming parameters remove inter-symbol interference in a communication channel.

A high-speed interconnect in accordance with an eighty sixth embodiment includes the features of the fifty first through eighty fifth embodiments, wherein the transmitter transmits data at speeds greater than one gigabit per second.

A high-speed interconnect in accordance with an eighty seventh embodiment includes the features of the fifty first through eighty sixth embodiments, further including at least a second re-driver.

A re-timer in accordance with an eighty eighth embodiment including a continuous time linear equalizer (CTLE); an amplifier; a transmit finite impulse response (FIR) driver; a clock and data recovery (CDR) circuit capable of extracting a clock and a data signal from the transmitted signals, where the CDR is also capable of regenerating a new transmitted signal using the transmit FIR driver; and a microcontroller capable of managing the automatic adaptation of the CTLE, amplifier, and FIR driver; wherein the microcontroller is further capable of utilizing the CDR to sample an analog signal transmitted by a transmitter via a channel, where the transmitted analog signal is a pulse; characterize the channel based upon the sampled analog signal; generate parameters that are capable of being used by the transmitter to program an equalizer; and transmit the generated parameters to the transmitter.

A re-timer in accordance with an eighty nineth embodiment includes the features of the eighty eighth embodiment, wherein the microcontroller implements a finite state machines that manages the automatic adaptation of the CTLE, amplifier, and transmit FIR driver.

A re-timer in accordance with a ninetieth embodiment includes the features of the eighty eighth and eighty nineth embodiments, further including a decision feedback equalizer (DFE) that processes signal reflections by the channel.

A re-timer in accordance with a ninety first embodiment includes the features of the eighty eighth through ninetieth embodiments, wherein the duration of the pulse is greater than a time required for transients caused by reflections of the pulse within the channel to have settled.

A re-timer in accordance with a ninety second embodiment includes the features of the eighty eighth through ninety first embodiments, wherein the microcontroller is further capable of utilizing the CDR to measure a channel impulse response based upon the sampled analog signal; and characterize the channel based upon the sampled analog signal comprises taking a derivative of the measured channel impulse response.

A re-timer in accordance with a ninety third embodiment includes the features of the eighty eighth through ninety second embodiments, wherein the generated parameters are capable of being used by the transmitter to program an equalizer that is a Feed Forward Equalizer (FFE) having a plurality of taps, where the number of the plurality of taps of the FFE corresponds to a duration of time that is equal to or greater than the time required for transients caused by reflections of the pulse within the channel to have settled.

A method for performing link training of a high speed serial link in accordance with a ninety fourth embodiment includes transmitting, by a transmitter, an analog signal via a channel, where the transmitted analog signal is a pulse; and the transmitter generates the pulse using a feed forward equalizer. The method further includes sampling, at a re-driver, an analog signal received via the channel; characterizing, at the re-driver, the channel based upon the sampled analog signal; generating, at the re-driver, FFE parameters that are capable of being used by the transmitter to program the FFE; and transmitting, by the extension device, the generated FFE parameters to the transmitter; configuring, by the transmitter, the FFE using the generated parameters.

A method for performing link training of a high speed serial link in accordance with a ninety fifth embodiment includes the features of the ninety fourth embodiment, wherein the re-driver includes a programmable analog signal path. The method further includes transmitting, by a transmitter, a second analog signal via the channel, where the transmitted second analog signal is a pulse generated using the FFE and after the transmitter has configured the FFE using the generated FFE parameters; sampling, at the re-driver, a second analog signal received via the channel; characterizing, at the re- driver, the channel based upon the second sampled analog signal; generating, at the re- driver, analog signal path parameters that are capable of being used by the re-driver to program the programmable analog signal path; and programming, by the re-driver, the programmable analog signal path using the generated analog signal path parameters.

A method for performing link training of a high speed serial link in accordance with a ninety sixth embodiment includes the features of the ninety fifth embodiment, wherein the re-driver generates the analog signal path parameters using a cost function.

A method for performing link training of a high speed serial link in accordance with a ninety seventh embodiment includes the features of the ninety fifth and ninety sixth embodiments, further including transmitting, by a transmitter, an analog data signal via the channel using the FFE after the programmable analog signal path of the re-driver has been programmed using the generated analog signal path parameters; receiving, at the re-driver, an analog data signal received via the channel; and amplifying, by the programmable analog signal path of the re-driver, the received analog data signal.

A method for performing link training of a high speed serial link in accordance with a ninety eighth embodiment includes the features of the ninety fourth through ninety seventh embodiments, wherein the programmable analog signal path comprises a programmable linear equalizer and a programmable variable gain amplifier.

A method for performing link training of a high speed serial link in accordance with a ninety nineth embodiment includes the features of the ninety fifth through ninety seventh embodiments, wherein the duration of the pulse of the first analog signal is greater than a time required for transients caused by reflections of the pulse within the channel to have settled.

A method for performing link training of a high speed serial link in accordance with a hundredth embodiment includes the features of the ninety fourth through ninety nineth embodiments, wherein the duration of the pulse of the first analog signal is greater than a time required for transients caused by reflections of the pulse within the channel to have settled.

A method for performing link training of a high speed serial link in accordance with a hundred and first embodiment includes the features of the ninety fourth through hundredth embodiments, further including measuring a channel impulse response based upon the sampled analog signal received via the channel; and characterizing the channel based upon the sampled analog signal comprises taking a derivative of the measured channel impulse response.

A method for performing link training of a high speed serial link in accordance with a hundred and second embodiment includes the features of the ninety fourth through hundred and first embodiments, wherein the FFE has a plurality of taps, where the number of the plurality of taps corresponds to a duration of time that is equal to or greater than the time required for transients caused by reflections of the pulse of the analog signal within the channel to have settled.

A method for performing link training of a high speed serial link in accordance with a hundred and third embodiment includes the features of the ninety fourth through hundred and second embodiments, wherein the re-driver device transmits the generated parameters to the transmitter via a content management interoperability services (CMIS) interface.

A high-speed interconnect in accordance with a hundred and fourth embodiment includes a transmitter and a re-driver configured to perform methods including the features of the ninety fourth through hundred and third embodiments.

A high-speed interconnect in accordance with a hundred and fifth embodiment includes a transmitter including a feed forward equalizer; and a re-driver including a programmable analog signal path; wherein the transmitter and re-driver are configured to periodically perform the methods including the features of the ninety fourth through hundred and fourth embodiments to periodically update parameters of the FFE of the transmitter and/or the programmable analog-signal path of the re-driver in response to observed channel impairments.

A linear pluggable optics in accordance with a hundred and sixth embodiment includes the re-driver of the first through thirty seventh and forty fourth through forty sixth embodiments directly packed with optics and connected to a processing unit through a copper interconnect.

A near package optics in accordance with a hundred and seventh embodiment includes the re-driver of the first through thirty seventh and forty fourth through forty sixth embodiments packed with optics and implemented as an intermediary between a processing unit and an optical connector.

A co-package optics in accordance with a hundred and eighth embodiment includes the re-driver of the first through thirty seventh and forty fourth through forty sixth embodiments and optics that are implemented together with a processing unit, where the co-packaged optics is coupled to an optical connector directly by a fiber interconnect.

A high-speed interconnect in accordance with a hundred and nineth embodiment includes the features of the fiftieth through eighty seventh embodiments, where the high-speed interconnect connects two processing units using copper interconnects connected to an active copper cable (ACC).

A high-speed interconnect in accordance with a hundred and tenth embodiment includes the features of the fiftieth through eighty seventh embodiments, where the high-speed interconnect connects a central processing unit (CPU) and a PCIe Switch using copper interconnects.

A high-speed interconnect in accordance with a hundred and eleventh embodiment includes the features of the hundred and tenth embodiment, wherein the PCle switch connects to a GPU via a high-speed interconnect including the features of the fiftieth through eighty seventh embodiments using copper interconnects.

A high-speed interconnect in accordance with a hundred and twelfth embodiment includes the features of the fiftieth through eighty seventh embodiments, where the high-speed interconnect connects a compute express link memory module (CXL MEM) and a PCle Switch using copper interconnects.

A high-speed interconnect in accordance with a hundred and thirteenth embodiment includes the features of the fiftieth through eighty seventh embodiments, wherein the PCle switch connects to a network interface controller (NIC) via a high-speed interconnect of any of claims 50 to 87 using copper interconnects.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIG. 1 illustrates a prior art re-timer.

FIG. 2 illustrates a prior art re-driver.

FIG. 3A illustrates an intelligent re-driver in accordance with an embodiment of the invention.

FIG. 3B illustrates an alternative re-driver configuration in which a clock is received from a synchronous clock source or a synchronous neighboring channel in accordance with an embodiment of the invention.

FIG. 3C illustrates another re-driver configuration including a skew adjuster in accordance with an embodiment of the invention.

FIG. 3D illustrates a re-driver configuration utilizing a crystal oscillator for phase locking in accordance with an embodiment of the invention.

FIG. 3E illustrates a clock recovery unit in accordance with an embodiment of the invention.

FIG. 3F illustrates a state machine implemented on an MCU for controlling a VCO in a clock recovery unit of a re-driver in accordance with an embodiment of the invention.

FIG. 4 illustrates a conceptual implementation of an intelligent re-driver in accordance with an embodiment of the invention.

FIG. 5 illustrates a link training process that can be employed during a setup mode in accordance with an embodiment of the invention.

FIG. 6 illustrates an iterative link training process that can be employed during a mission mode (involving live data transmission) in accordance with an embodiment of the invention.

FIGS. 7A-7B illustrate a comparison of signal quality before and after link training in accordance with an embodiment of the invention.

FIGS. 8A-8C illustrate implementations of intelligent re-drivers in communication systems in accordance with several embodiments of the invention

FIGS. 9A-9C illustrate implementations of intelligent re-drivers in copper interconnects in accordance with several embodiments of the invention.

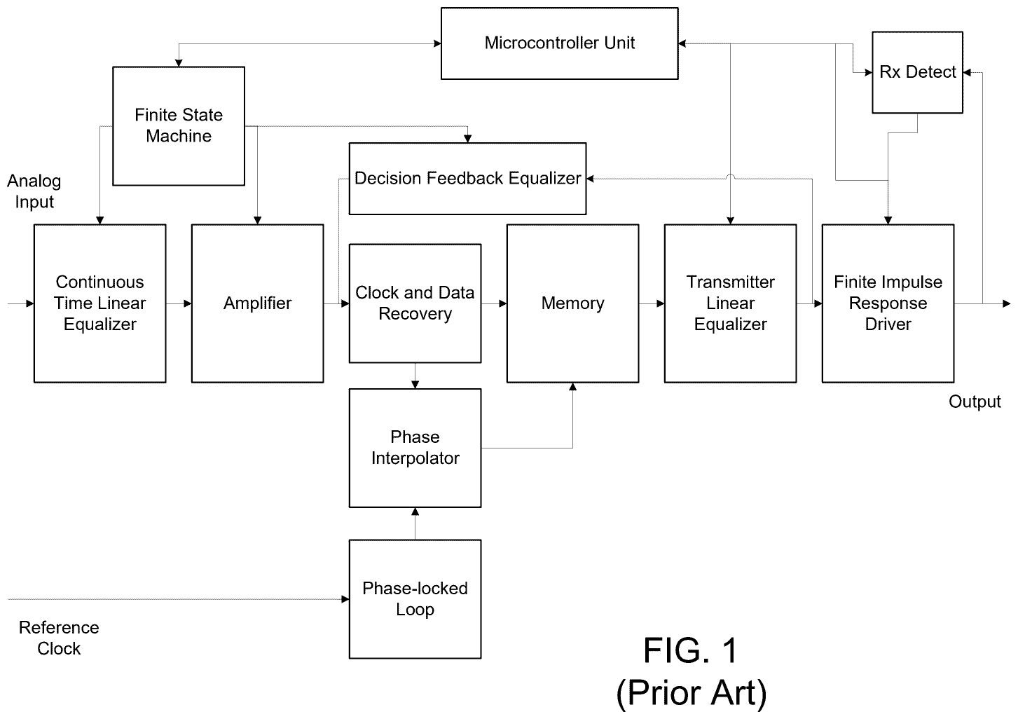

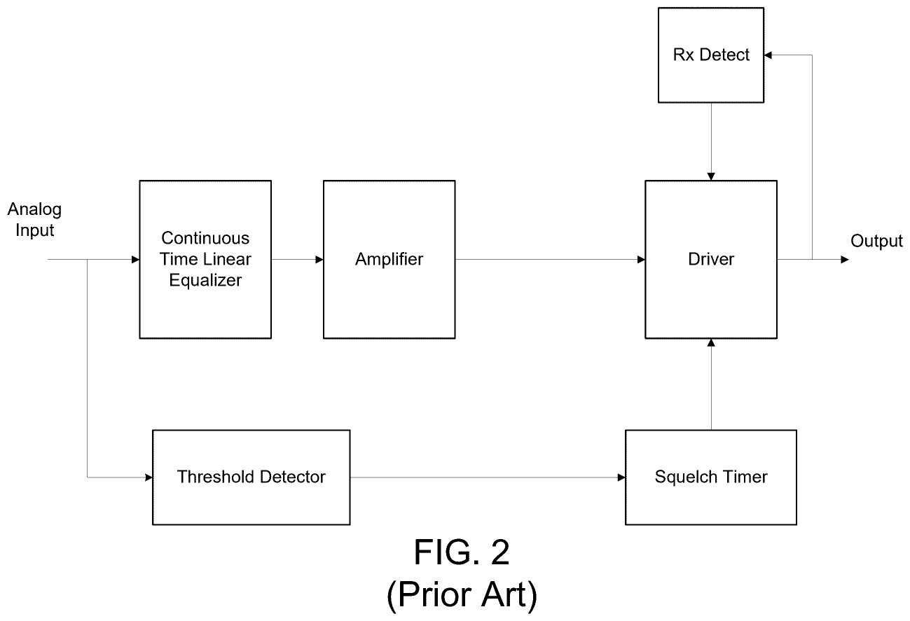

### DETAILED DESCRIPTION

Turning now to the drawings, high-speed serial links and methods of redriving signals in accordance with various embodiments of the invention are illustrated. The demand for processing power in High Performance Computing, Artificial Intelligence (AI) and Machine Learning is increasing at an unprecedented rate. The emergence of Large Language Models (LLMs) has highlighted the importance of memory bandwidth and interconnect speed within computer systems as the number of parameters used by LLMs has increased at a rate that is orders of magnitude greater than the rate at which the memory bandwidth and interconnect speed of Graphics Processing Units (GPUs) has been increasing. Accordingly, interconnect latency can be critical to AI applications in a way that has not previously been the case in many of the other networking applications in which high-speed serial links have traditionally been utilized. The low latency requirements of AI applications can be challenging for DSP-based re-timers, which introduce latency in order to enable regeneration of signals. Additionally, DSP-based re-timers may consume large amounts of power when attempting to connect high density and high-speed electronic signals from application-specific integrated circuits (ASICs), which may further increase latency as well as bit-error rate. While conventional analog-based re-drivers can experience lower latency than re-timers, they typically suffer from performance issues due to an inability to adapt based on channel conditions.

Non-Complementary Metal-Oxide-Semiconductor (CMOS) linear analog solutions lack the digital intelligence that is required to have a reliable plug and play solution.

High-speed serial links implemented in accordance with various embodiments of the invention can provide low latency and low power consumption, which can enable the construction of computing systems with low latency and low power interconnects. In a number of embodiments, the high-speed serial links are implemented using intelligent re-drivers that utilize low latency programmable analog components and which are capable of performing digital link adaptation to compensate for channel impairments. Intelligent re-drivers in accordance with various embodiments can be implemented with low-cost CMOS technology, and function as a plug and play module that can be seamlessly integrated into communication systems. In numerous embodiments, the intelligent re-drivers can actively monitor and sample transmitted signals, which can enable the re-driver to re-configure its programmable analog components to counteract channel impairments as well as provide optimized settings to an upstream transmitter Feed Forward Equalizer (FFE). In addition, intelligent re-drivers in accordance with many embodiments of the invention can enable performance monitoring. Furthermore, intelligent re-drivers in accordance with various embodiments of the invention can incorporate low-power and high-swing output drivers for use in combination with interconnects including (but not limited to) copper and/or optical interconnects. In this way, intelligent re-drivers in accordance with various embodiments of the invention can be utilized in a variety of applications including interfaces similar to (but not limited to) PCIe, Infiniband, and ultra Ethernet.

The ability of intelligent re-drivers in accordance with embodiments of the invention to characterize a communication channel can enable the establishment of optimized transmitter and receiver settings within the communication system. It is important that this characterization is done accurately and that it produces parameters that can be incorporated in the transmitter and receiver units to compensate for various observed channel impairments such as (but not limited to) insertion loss and return loss. By optimizing the settings in the transmitter and/or receiver for a given target bit error rate, the data transmission rate at a given power consumption can be increased. Conversely, for a given power and data rate, the bit error rate can be reduced.

In several embodiments, the intelligent re-drivers include a programmable linear equalizer that can be configured to compensate for signal distortions observed to result from transmission through the channel. In many embodiments, the channel attenuates transmitted signals at higher frequencies more than at lower frequencies and the linear equalizer can be programmed to boost the higher frequency components of the signal to bring all frequency components of the signal to a similar amplitude, improving jitter and eye diagram performance. In selected embodiments, the intelligent re-drivers also include a variable gain amplifier that can be configured to provide a variable gain to the output of the linear equalizer to maintain a suitable signal amplitude at the input to an output driver. Re-drivers in accordance with certain embodiments of the invention also include the capability to sample and digitize the samples of the output signal and use this digital information to control the configuration of the programmable linear equalizer and/or other programmable analog components within the re-driver including (but not limited to) the variable gain amplifier.

In many embodiments, the intelligent re-drivers include an analog to digital converter (ADC) to digitize the analog signal being transmitted and a microcontroller unit (MCU) that can analyze the digital signal. In several embodiments, the ADC can run at a slower rate than the symbol rate of the communication channel. In a number of embodiments, the microcontroller unit (MCU) can analyze the digitized signal to extract parameters that can be used to adjust the various analog components used in the transmission of the signal in a manner that compensates for channel impairments including (but not limited to) components in the transmitter (e.g. an FFE) and/or components in the re-driver (e.g. a programmable linear equalizer and/or a programmable variable gain amplifier). In certain embodiments, all of the components of the intelligent re-driver can be incorporated within a single integrated circuit. In many embodiments, the ADC and/or the MCU may be located on a separate integrated circuit(s) from the integrated circuit that implements the rest of the components of the intelligent re-driver.

Intelligent re-drivers and methods of re-driving signals in accordance with various embodiments of the invention are discussed further below.

### Intelligent Re-drivers

Intelligent re-drivers in accordance with many embodiments of the invention can utilize low-latency analog building blocks in the signal path such as (but not limited to) a programmable linear equalizer, a programmable variable gain amplifier, and a line driver. In selected embodiments, re-drivers utilize an ADC that runs at a lower speed than the symbol rate of the channel (a sub-sampling ADC) to digitize samples of the analog signal. In many embodiments, the impact of sampling the signal path is minimized by using buffers with minimum loading to tap into the signal path. As can readily be appreciated, any of a variety of techniques can be utilized to sample the signal path as appropriate to the requirements of specific applications. Digitized signals can be fed to a digital processing unit, such as (but not limited to) an MCU, in order to compute parameters that can be used to adjust the operation of the programmable analog components that form the signal path in a manner that compensates for channel impairments. In this way, intelligent re-drivers implemented in accordance with various embodiments of the invention can combine digital link adaptation, performance monitoring, low-latency, low-power, and/or high-swing capabilities. In addition, intelligent re-drivers can also optimize the tuning of an upstream transmitter FFE.

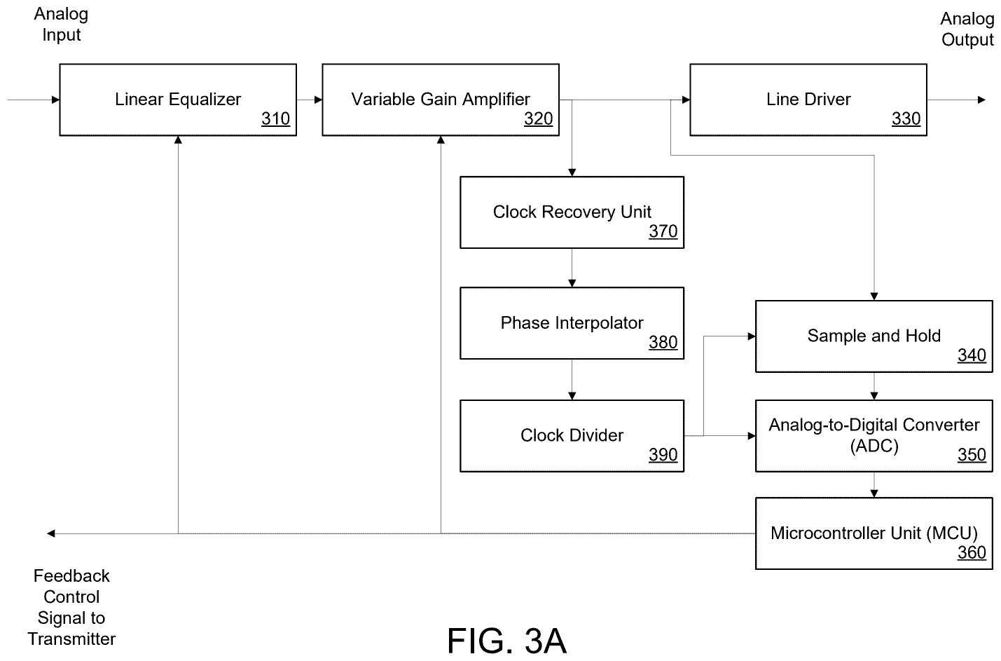

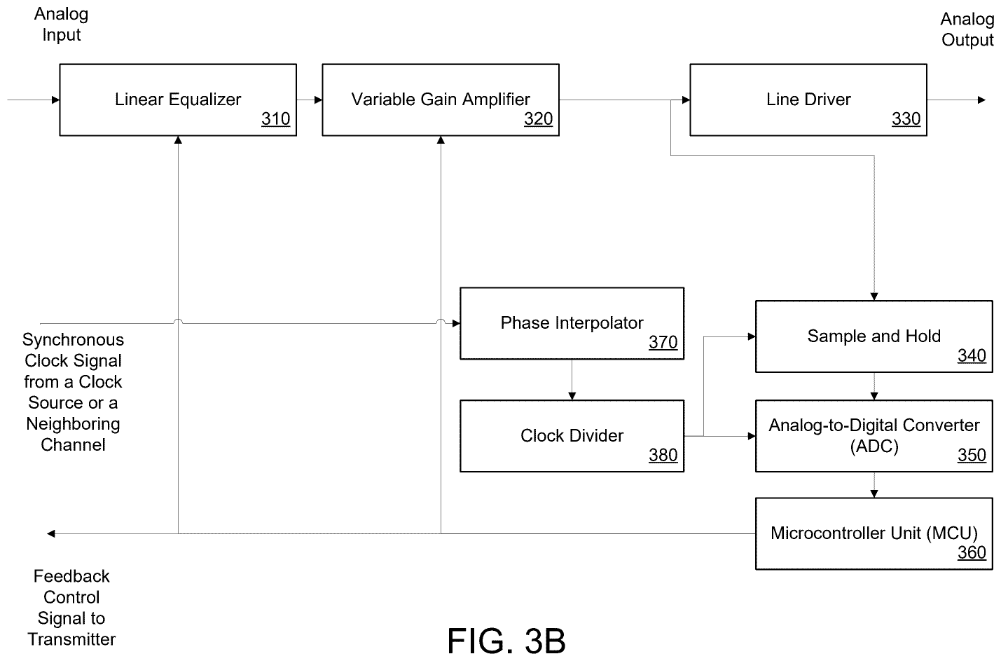

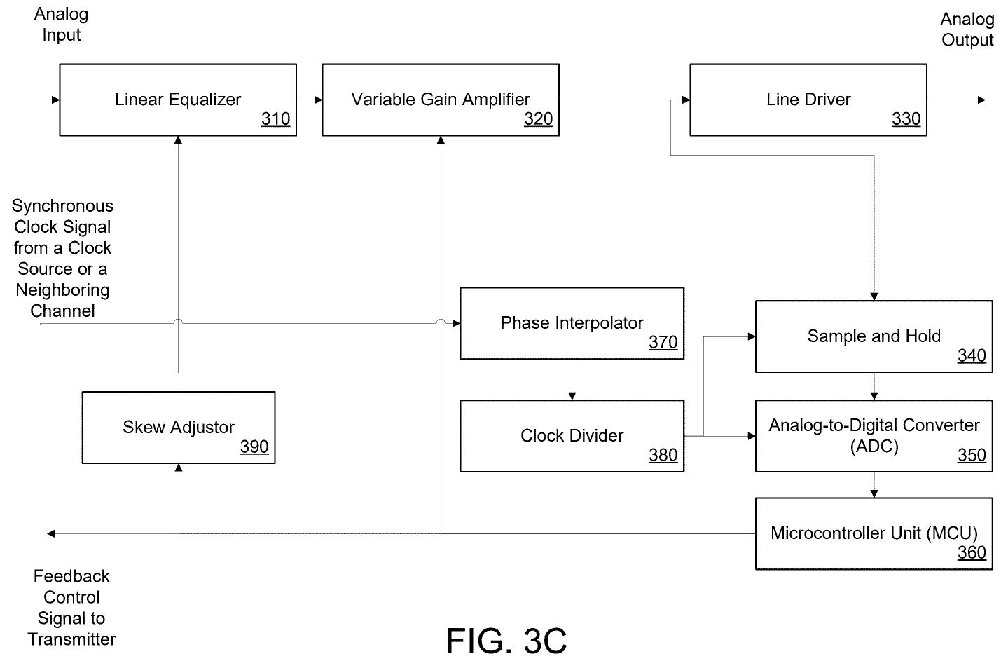

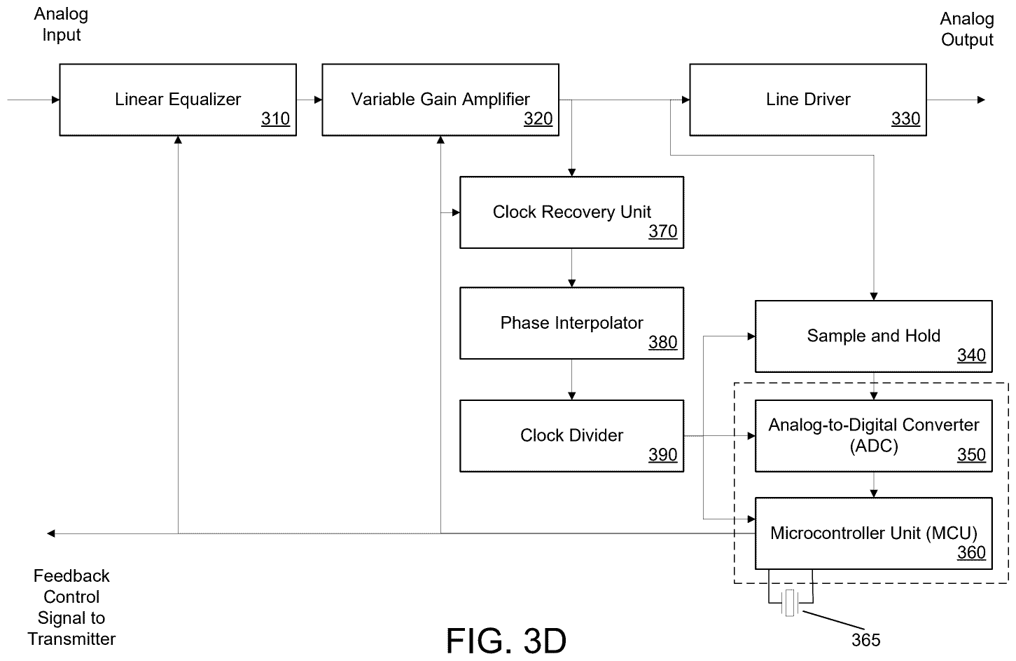

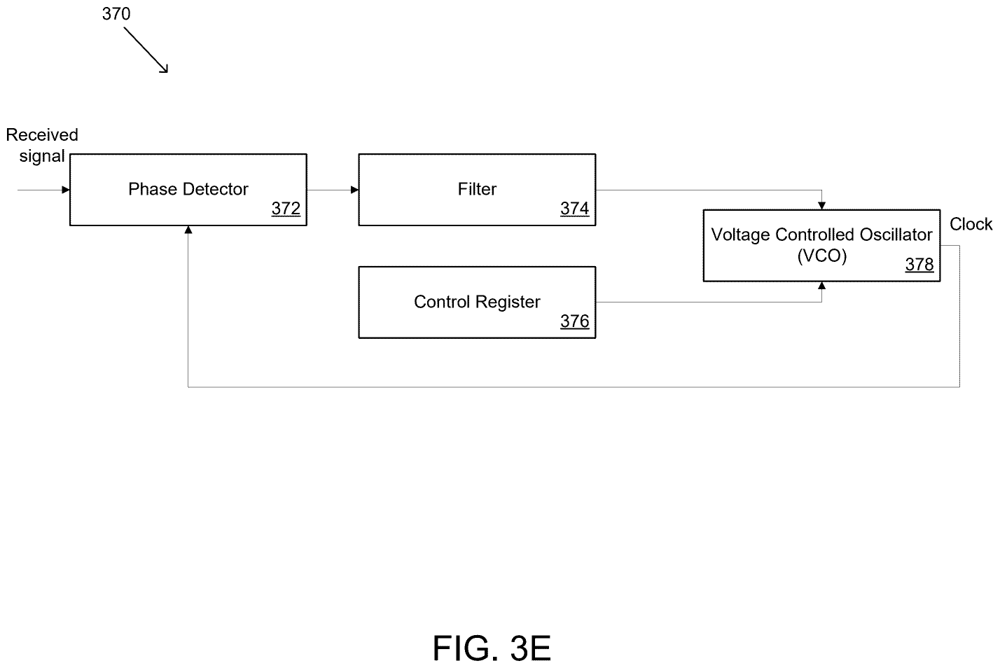

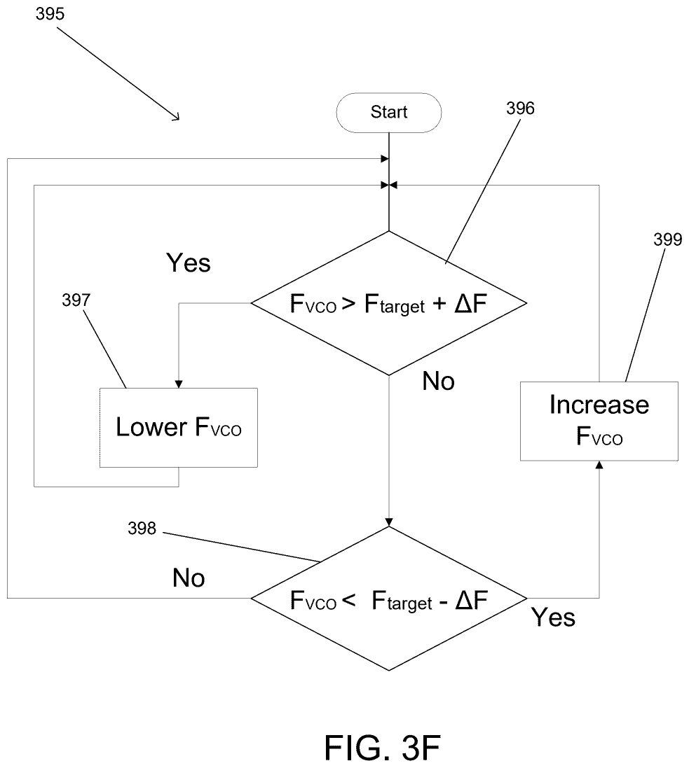

An intelligent re-driver in accordance with an embodiment of the invention is illustrated in FIG. 3A. The re-driver 300 includes a programmable linear equalizer 310, a programmable variable gain amplifier 320, and a line driver 330. In the illustrated embodiment, the re-driver 310 receives an analog input at the programmable linear equalizer 310 and provides an equalized output to the programmable variable gain amplifier 320. Programmable linear equalizers in accordance with some embodiments of the invention are implemented using a continuous time linear equalizer (CTLE). The programmable variable gain amplifier 320 can adjust the gain of the signal that it receives in order to maintain a suitable signal amplitude at the input of the output driver 330. In the illustrated embodiment, the linear equalizer 310, variable gain amplifier 320, and line driver 330 are shown as directly connected. As can readily be appreciated, additional analog components can be utilized to form a signal path including a linear equalizer, a variable gain amplifier, and a line driver as appropriate to the requirements of specific re-driver applications in accordance with various embodiments of the invention.

In many embodiments, re-drivers also include components that enable digital link adaptation. In the illustrated embodiment, the re-driver 300 includes sample and hold circuitry 340, an analog to digital converter (ADC) 350, and a microcontroller unit (MCU) 360 to enable the capture of digital samples of the signal within the signal path and to use that information to program the programmable components within the analog signal path including (but not limited to) the programmable linear equalizer 310, and the programmable variable gain amplifier 320. In many embodiments, the MCU can also communicate with the upstream transmitter and is capable of using information characterizing the channel to update the parameters utilized to configure the upstream transmitter. In a number of embodiments, the re-driver can communicate with transmitters for updates through an interface including (but not limited to) content management interoperability services (CMIS).

As is discussed further below, the re-driver can digitize the channel response by recovering a sampling clock. In the illustrated embodiment, the re-driver further includes a clock recovery unit 370, a phase interpolator 380, and a clock divider 390 that can be configured to enable recovery of the sampling clock. An alternative re-driver configuration in accordance with an embodiment of the invention is illustrated in FIG. 3B. In the illustrated embodiment, the sampling clock signal is generated by a synchronous clock source or a synchronous neighboring channel instead of the transmitted signal. As can be readily appreciated, intelligent re-drivers in accordance with several embodiments of the invention can include configurable circuitry enabling clock recovery from either the signal path or a neighboring channel as appropriate to the requirements of specific applications.

In situations where the transmitted signals are differential, there may be a skew between the positive and negative signals of the differential signals when the data rate is high. A re-driver configuration including a skew adjustor in accordance with an embodiment of the invention is illustrated in 3C. Intelligent re-drivers in accordance with various embodiments may further include a skew adjustor 390 that can monitor and measure skews in transmission. In some embodiments, intelligent re-drivers can adjust the delay in transmission.

In several embodiments, the MCU of an intelligent re-driver is capable of scanning and sampling the signal inside the receiver during normal operation. In this way, the MCU can provide for a more traditional signal capture (e.g. eye monitoring). Using eye monitoring, the MCU can enable analysis during a live or mission mode, with actual data patterns. In addition, the MCU can enable system testing, with stress test patterns. In many embodiments, a digital eye monitor (DEM) monitors the eye graph of transmitted signals and (manual) adjustments can be made to programmable components to minimize impairments including (but not limited to) inter-symbol interference (ISI). DEMs in accordance with several embodiments of the invention can be configured by the MCU to perform monitoring when needed and with respect to a variety of signals including (but not limited to) NRZ and PAM4 signals. In several embodiments, if the forward error correction (FEC) error goes beyond an acceptable limit, a re-driver can report eye statistics captured using the DEM. This can enable the re-driver to provide link accountability to an operator and help them locate the components in the link (e.g. laser, fiber, etc.) that may be responsible for the excess error rate.

As noted above, re-drivers in accordance with various embodiments of the invention, including (but not limited to) re-drivers similar to those described above with respect to FIGS. 3A-3C, can be implemented on a single integrated circuit or using multiple integrated circuits. In many embodiments, a re-driver integrated circuit component is implemented that provides an analog output for digitizing by an external ADC and processing of the digitized signal by an external MCU. In several embodiments, multiple re-drivers share an MCU and, in many embodiments, multiple re-drivers are connected in series and share an MCU. Intelligent re-drivers in accordance with a variety of embodiments can output to a DEM for link monitoring and diagnostics.

Re-drivers in accordance with several embodiments of the invention, including (but not limited to) re-drivers similar to those described above with respect to FIGS. 3A-3C, can be implemented using a 22 nm FDSOI process using high-speed analog/mixed-signal design techniques. Re-drivers implemented using these processes can achieve 50% lower power consumption than equivalent SiGe processes.

In several of the embodiments described above, the re-driver characterizes the channel response by receiving and sampling a clock signal transmitted by the up-stream device (see e.g. FIG. 3A). In a number of embodiments, the MCU is capable of providing control signals to a voltage controlled oscillator (VCO) within the clock recovery unit of the re-driver to frequency lock the VCO to a reference signal. In many embodiments, the reference signal is a signal generated by a stable source such as (but not limited to) a crystal oscillator. Once the VCO is frequency locked, the clock recovery unit can then phase lock the VCO based upon the channel response using a phase lock loop (PLL). In this way, the output of the VCO can be used to generate a sampling clock signal. In a number of embodiments, the sampling clock signal has a frequency that is sufficiently high to oversample pulses transmitted during link training. As discussed above, during normal mode (data communication mode) the sampling clock signal has a frequency that is lower than the symbol rate of the transmitted data so that the transmitted data signal is under sampled by the re-driver.

A re-driver in which an MCU utilizes a crystal oscillator to perform frequency locking of a VCO with a clock recovery unit of a re-driver in accordance with an embodiment of the invention is illustrated in FIG. 3D. In the configuration illustrated by FIG. 3D, the components of the re-driver are integrated into a first component except for the ADC 350, the MCU 360 and a crystal oscillator 365. The ADC 350 and MCU 360 are integrated into a second component that is connected via various connections to the first integrated component. The crystal oscillator 365 is also connected to the second component and provides a stable clock signal to the MCU 360.

In the illustrated embodiments, the clock recovery unit 370 includes a voltage controlled oscillator that can be controlled by input signals received from the MCU 360. The MCU 360 can utilize the clock signal provided by the crystal oscillator 365 to generate a reference signal. In certain embodiments, the MCU 360 utilizes a divider to divide the clock signal received from the crystal oscillator 365 to generate the reference signal. The MCU can compare the clock signal output by the clock divider 390 to the reference signal and, based upon the comparison, provide input signals to the clock recovery unit 370 that can be utilized to control the frequency of the VCO. In a number of embodiments, the MCU can provide inputs to the clock recovery unit 370 that increase, decrease, or hold steady the frequency of the VCO.

A clock recovery unit that can be utilized within re-drivers (including but not limited to the re-driver of FIG. 3D) in accordance with an embodiment of the invention is illustrated in FIG. 3E. The clock recovery unit 370 includes a phase detector 372, a filter 374, a control register 376, and a voltage controlled oscillator 378. As discussed above, an MCU can provide control signals to the clock recovery unit that cause the VCO to lock to a stable reference frequency that is very close to the reference frequency of the signal received via the channel. The clock recovery unit utilizes the received control signals to adjust the frequency of the VCO by altering the value stored within the control register 376. The components of the clock recovery unit 370 implement a phase lock loop (PLL) that causes the frequency locked output of the VCO to lock to the phase of the received signal. In this way, the clock recovery unit 370 is able to recover a sampling clock signal from the signal received by the re-driver via the channel.

While specific clock recovery units in accordance with various embodiments of the invention are described above with reference to FIG. 3E, clock recovery units can be implemented using any of a variety of different configurations including alternative and/or additional components to recover clock signal from signals received by the re-driver via the channel as appropriate to the requirements of specific applications in accordance with various embodiments of the invention.

In a number of embodiments, the re-driver includes an MCU that implements a state machine that generates control signals for a clock recovery unit based upon a comparison of a clock signal generated by a VCO within the clock recovery unit and a reference signal that is generated based upon a clock signal received, by the MCU, from a crystal oscillator. A state machine diagram of a state machine implemented using machine readable instructions that are executed by an MCU in accordance with an embodiment of the invention is illustrated in FIG. 3F. In the example illustrated by FIG. 3F, the MCU performs a process 395 in which the MCU obtains a reference signal that is generated based upon a clock signal generated by a crystal oscillator. The MCU can use the reference signal to determine command signals to send to a VCO in a clock recovery unit in order to frequency lock the clock signal generated by the VCO to the reference signal.

In the illustrated embodiment, the MCU determines (396) whether the frequency of the oscillator is greater than the target frequency by more than acceptable margin. If yes, then the MCU generates (397) a control signal that instructs the clock recovery unit to decrease the frequency of the VCO. Otherwise, the MCU determines (398) whether the frequency of the oscillator is less than the target frequency by more than acceptable margin. If yes, then the MCU generates (399) a control signal that instructs the clock recovery unit to increase the frequency of the VCO. Otherwise, the MCU does not modify the frequency of the VCO and continues to compare the frequency of the VCO to the frequency of the reference signal generated based upon the signal produced by the crystal oscillator.

While a specific process that can be utilized by an MCU to generate control signals for controlling the frequency of a VCO within a clock recovery unit are described above with respect to FIG. 3F, any of a variety of process can be implemented using an MCU to generate control signals for a VCO as appropriate to the requirements of specific applications in accordance with various embodiments of the invention.

While specific re-drivers for low latency communication in accordance with various embodiments of the invention are described above with reference to FIGS. 3A-3F, re-drivers can be implemented using any of a variety of different configurations including alternative and/or additional components to provide an analog signal path and the ability to perform digital link adaptation as appropriate to the requirements of specific applications in accordance with various embodiments of the invention.

### Link Training and Monitoring Processes

HSIs that incorporate intelligent re-drivers in accordance with many embodiments of the invention undergo link training to adjust for the channel impairments that may be detected. While much of the discussion that follows focuses on the use of link training in the context of re-drivers, similar link training processes can also be utilized within re-timers. The use of various link training processes that involve characterizing the channel and utilizing the channel characteristics to determine parameters for an equalizer within an upstream transmitter in re-drivers and re-timers in accordance with various embodiments of the invention are discussed further below.

A communication channel can be characterized by its step or pulse response. High-speed serial links in accordance with various embodiments of the invention may include a transmitter capable of transmitting a periodic two-level signal to the re-driver (receiver) for the digital link adaptation circuitry within the re-driver to capture the channel response. This signal can be easily detected and used as a sampling clock by clock recovery circuitry within the re-driver to digitize the channel response. By using a two-level signal with a low frequency over the channel-under-test, the sampling clock can be readily extracted, and the same signal can be used for digitizing the channel response. In many embodiments, the duration of the pulse that is utilized to characterize the channel is sufficiently long so that all of the transients associated with reflections within the channel have settled within the period of the pulse. In a number of embodiments, the receiver can completely characterize the channel by taking a derivative of the pulse response. As discussed further below, the channel response can then be utilized to determine parameters that the transmitter can utilize to reduce or eliminate inter-symbol interference (ISI) within the transmitted signal by pre-distorting the signal to compensate for channel distortion, thereby improving received signal quality.

Various embodiments capture channel responses caused by the transmission channel based upon the clock signal. In several embodiments, a clock recovery unit, a phase interpolator, and a clock divider (similar to those described above with respect to FIGS. 3A-3C) may be utilized in combination to recover a sampling clock. In certain embodiments, a clock signal can be received by the re-driver via a synchronous clock source or a synchronous neighboring channel. In accordance with many embodiments, the digital link adaptation circuitry of the re-driver can be configured to vary the sampling phase of the sampling clock, such that a “scan” can be performed. As can readily be appreciated, the specific manner in which the re-driver uses the recovered sampling clock to sample and analyze the channel characteristics is largely dependent upon the requirements of specific applications. In many embodiments, a clock signal is chosen such that the half-period of the clock signal is sufficiently long so that it is equal to or greater than the time required for all transients caused by reflections within the channel to have settled.

In several embodiments, intelligent re-drivers can operate at a very high frequency, and behave like a communication channel despite structurally being more like a digital bus. Intelligent re-drivers in accordance with many embodiments perform processing of signals such as Fast Fourier Transforms (FFT) on the transmitter side.

In various embodiments, systems and methods derive deterministic information regarding the transmission channel based on the captured impulse responses. When signals of pseudorandom binary sequences (PRBS) are sent (as is proposed for use in re-timers that include DSPs in both the transmitter and the receiver), the transmission channel needs to be deconvolved to determine information related to channel characteristics, making the process computationally expensive. However, transmission channels may be more readily analyzed when it is only a pulse being sent. The impulse response of the channel which completely characterizes the channel can be obtained by taking the derivative of the pulse response. Deterministic information regarding the transmission channel obtained from the impulse response of the channel may be used to adjust the transmitter to equalize the transmission channel. Re-drivers in accordance with several embodiments compute and set transmitter Feed-Forward Equalizer (FFE) and/or local Continuous Time Linear Equalization (CTLE) coefficients to remove ISI caused by the channel and the components that are responsible for signal reflections. Many current SERDES implementations use FFEs with a small number of taps. When the number of taps in the FFE represents a time period that is shorter than the duration of the channel response, the intelligent re-driver cannot completely eliminate ISI. However, characterizing the channel enables the intelligent re-driver to cause the parameters of the taps in the FFE to be set in a manner that effectively reduces ISI. In a number of embodiments, the intelligent re-driver is utilized in combination with a transmitter, where the SERDES has been implemented so that the FFE has a number of taps that corresponds to a time period that is equal to or greater than the duration of the channel response measured by the re-driver.

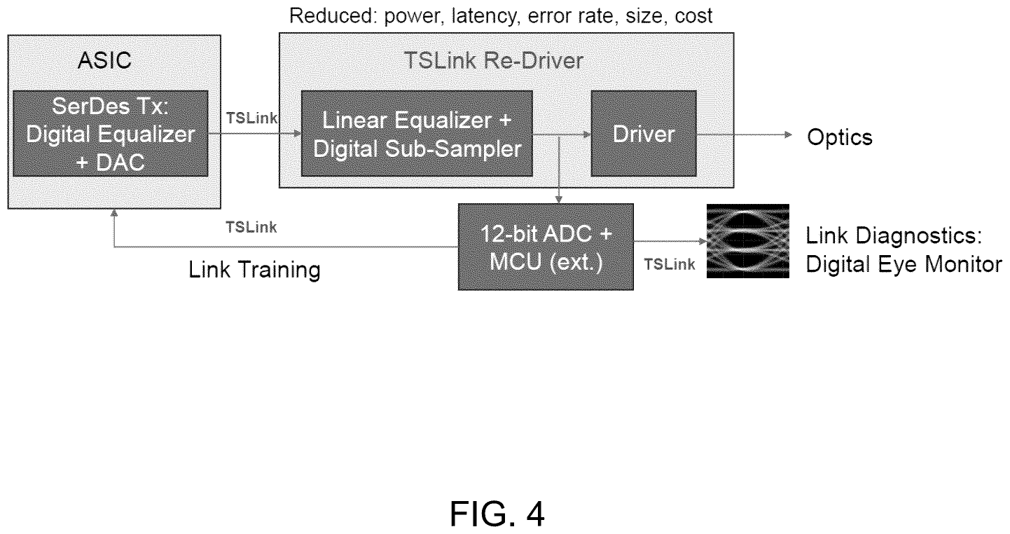

In many embodiments, link training and channel equalization are implemented with minimal to no DSP-based components in the receiver signal path, which can lead to lowered power consumption as well as lowered latency compared to DSP-based receivers. A conceptual implementation of an intelligent re-driver in accordance with an embodiment of the invention is illustrated in FIG. 4. Unlike low-resolution ADCs such as 4-5-bit ENOB ADCs used in DSP based receivers, intelligent re-drivers in accordance with various embodiments utilize a 12-bit ADC for link training and channel equalization which results in more accurate transmitter FEE and CTLE settings. Link training and channel equalization processes in accordance with several embodiments greatly reduce the need for manual tuning of transmitters, making the intelligent re-driver a plug and play solution for linear pluggable optics (LPO). In selected embodiments, the amounts of channel equalizations can be enhanced by increasing the number of tabs in the transmitter FFE. DEMs may be used to monitor the BER and adjust the CTLE setting during normal operations.

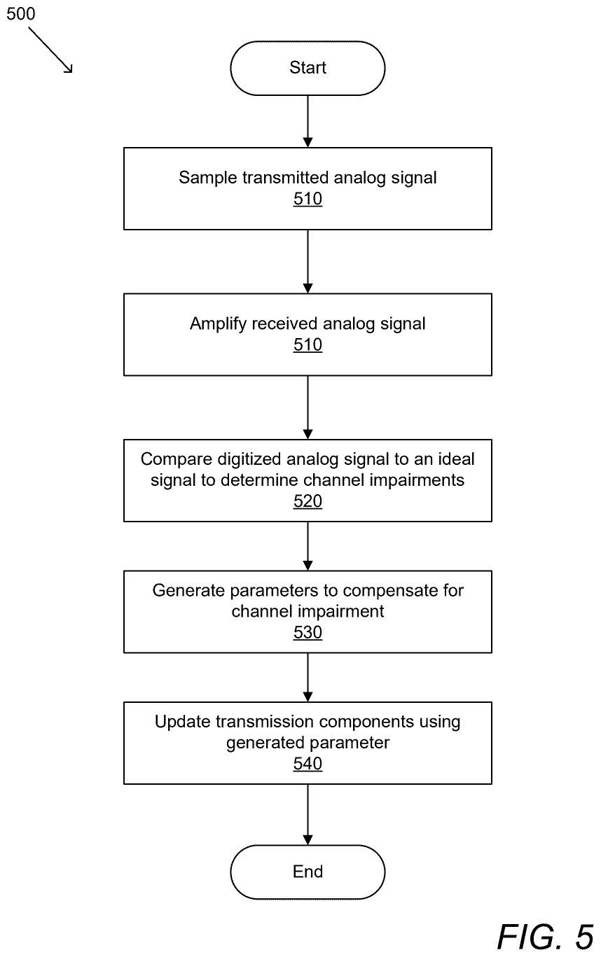

In certain embodiments, link training may be performed as part of a set up process at the start of an operation before any live traffic is communicated through the re-drivers. A link training process that can be performed during a re-driver setup mode in accordance with an embodiment of the invention is illustrated in FIG. 5. Process 500 samples (510) a transmitted analog signal. In many embodiments, the transmitted analog signal is sampled by an ADC that may be part of a single integrated circuit or implemented on a separate integrated circuit to the integrated circuit that performs the equalization of the analog signal within the re-driver.

In many embodiments, the analog signal is transmitted through the channel where the re-driver is deployed. In some embodiments, the transmitted analog signal may be a periodic unit pulse or a step. In many embodiments, initial pulses are utilized having widths that are long enough to characterize the channel but not so long as to materially increase setup time. As can readily be appreciated, the specific characteristics of the signal used to characterize the channel are largely dependent upon the requirements of specific applications. Process 500 amplifies (520) the received signal from the channel.

Process 500 compares (530) a digitized and amplified version of the sampled signal to an ideal signal and generates (540) a plurality of parameters that can be utilized to configure (550) the analog components of the re-driver to compensate for the measured channel impairment. In several embodiments, an MCU is configured to determine the modifications to apply to the equalization settings in the transmitter and/or receiver based on the digitized amplified signal. In a number of embodiments, the MCU can set the FFE coefficients for the transmitter, and/or parameters of the programmable analog components within the signal path of the re-driver including (but not limited to) the programmable linear equalizer and programmable variable gain amplifier. In several embodiments, the MCU can set the transmitter FFE coefficients using an interface such as (but not limited to) a CMIS interface to facilitate link training. Once the transmitter FFE coefficients have been set, the MCU can set the parameters utilized to configure the programmable components of the re-driver's analog signal path (e.g. a programmable linear equalizer and/or a programmable variable gain amplifier) using a cost function. As can readily be appreciated, the specific components that are programmed by the MCU to perform link adaptation and/or the order in which specific components are programmed by the MCU are largely dependent upon the requirements of specific applications.

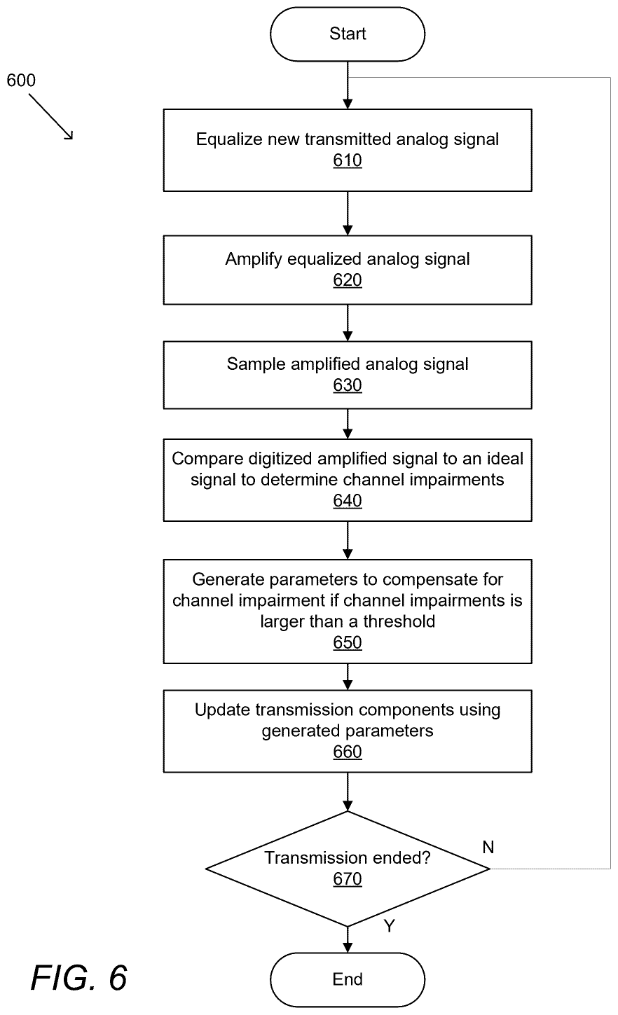

In some embodiments, link training may be performed as an iterative process, where the channel response with equalization is periodically compared to an ideal response in order to continuously update system parameters in response to changes in the observed channel impairments. FIG. 6 illustrates an iterative link training process that can be utilized by a re-driver in a live or mission mode, in which live data is transmitted, in accordance with an embodiment of the invention.

Process 600 equalizes (610) a newly transmitted analog signal and amplifies (620) the received analog signal. In several embodiments, transmitted analog signals are equalized using a linear equalizer on the re-driver, which can address distortion incurred by the analog signal due to transmission through the channel.

Process 600 samples (630) the amplified analog signal and compares (640) the digitized amplified signal to an ideal signal to determine channel impairments. If the channel impairments are determined to exceed a threshold (or otherwise are determined to be out of a desired operating configuration), process 600 can generate (650) updated parameters to compensate for the observed channel impairments and utilize the updated parameters to update (660) the configuration of at least one analog component either within the upstream transmitter and/or within the signal path of the re-driver. In several embodiments, the determined channel impairments may be reported to a user monitoring the transmission such that the user may exercise their own judgment in determining the proper compensation to the channel. User monitoring of link quality can be performed during live traffic without interfering with the transmission.

Process 600 determines (670) if additional optimization is required or the optimization process has otherwise ended. If the optimization process has not ended, process 600 can continue to monitor the transmitted analog signal and adjust the analog components of the re-driver based upon updated parameters generated in response to observed channel impairments.

While specific processes are described above with reference to FIGS. 5 and 6, any of a variety of methods for link training in any of a variety of different re-driver modes can be utilized as appropriate to the requirements of specific applications in accordance with various embodiments of the invention. For example, re-drivers in accordance with many embodiments of the invention can be utilized over long distances in communication systems such as (but not limited to) optical communication systems. In a number of optical communication systems, intelligent re-drivers can be utilized to characterize the optical channel response and to provide information via a feedback channel (e.g. a separate return path). Furthermore, the processes described above are not limited to performing link training utilizing intelligent re-drivers but can also be implemented within re-timers in accordance with various embodiments of the invention. As noted above, the SERDES utilized in the transmitter may also be implemented so that the FFE of the SERDES has a number of taps corresponding to a time duration that is equal to or greater than the channel response duration measured by the re-timer. As can readily be appreciated, the specific manner in which link training is performed based upon the channel impulse response is largely only limited by the requirements of specific applications and the processes described herein for performing link training can be utilized within any of the systems disclosed above.

Monitoring HSIs can be important for ensuring reliable data transmission and maintaining optimal performance in computing, networking, and storage systems. Effective monitoring can prevent failures, enhance security, and enable proactive debugging for mission-critical applications. In many embodiments, systems and methods can monitor network traffic during mission mode. For example, network traffic may be monitored through eye diagrams and/or signal-to-noise ratios (SNR) of the transmission. Only when a deterioration in performance is detected do the analysis of the transmission channel begin to obtain deterministic information regarding the channel. Re-drivers in accordance with many embodiments can be adjusted based on the deterministic information in a very short amount of time. In some embodiments, re-drivers may terminate network traffic after performing channel equalization. Re-drivers may behave like a serializer/deserializer (SERDES) and turn the transmitted signal into a digital signal such that the digital signal can be processed in the digital domain.

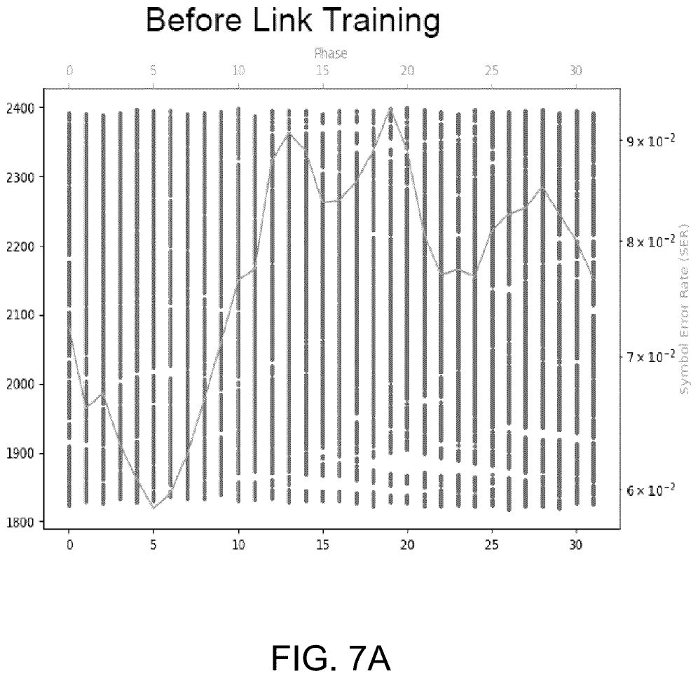

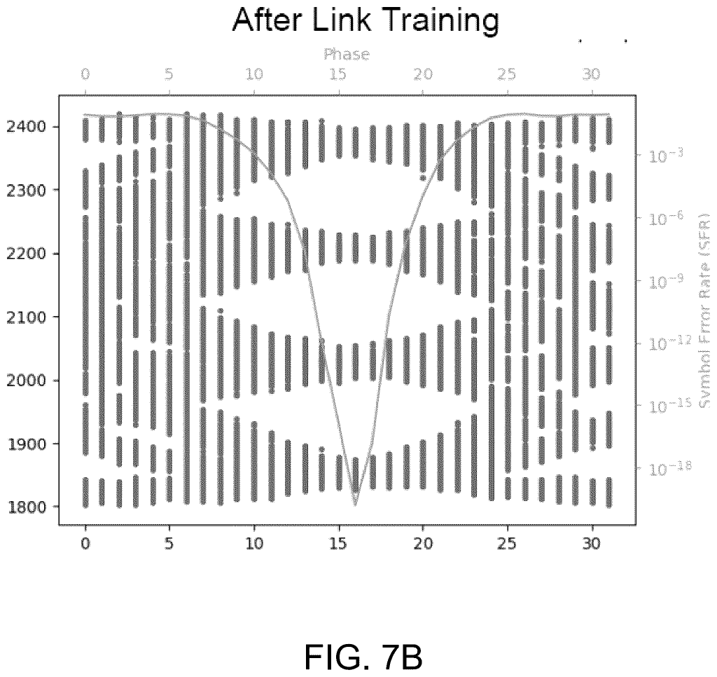

A comparison of signal quality before and after link training in accordance with an embodiment of the invention is illustrated in FIGS. 7A-B. As seen in FIG. 7B, eye diagrams of signals are more visible after link training, indicating a stronger signal integrity.

### Link Implementations

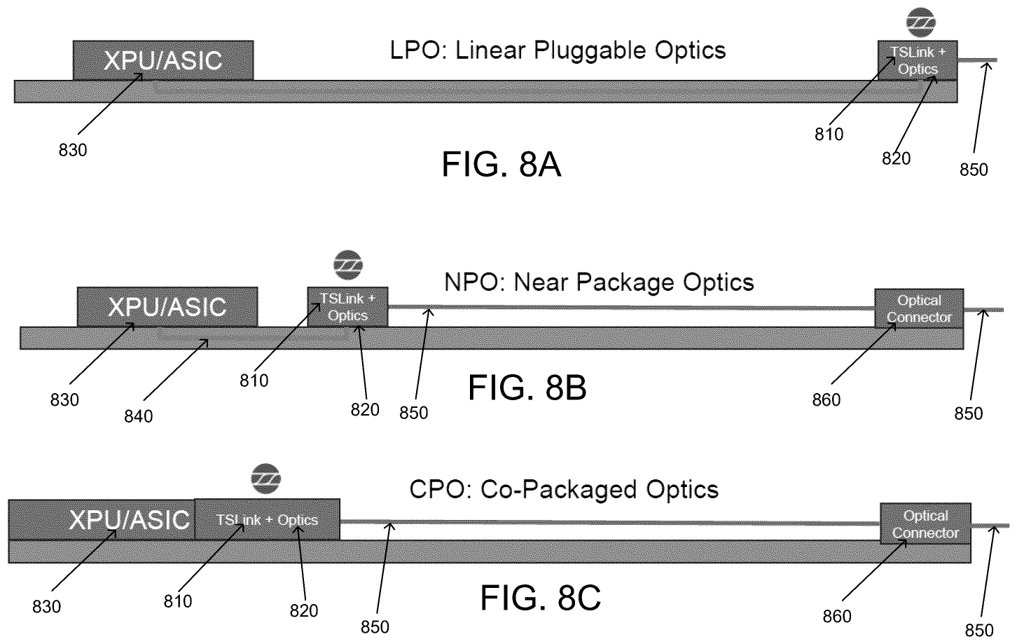

Intelligent re-drivers in accordance with many embodiments can be implemented as different solutions in communication systems including but not limited to LPO, near package optics (NPOs), and co-packaged optics (CPO). Implementations of intelligent re-drivers in communication systems in accordance with several embodiments of the invention are illustrated in FIGS. 8A-8C.

In the embodiment illustrated in FIG. 8A where an LPO solution is implemented, an intelligent re-driver 810 can be packaged directly with optics 820 and connected to a processing unit 830 through a copper interconnect 840 to transmit/receive through a fiber interconnect 850.

When implemented as an NPO solution as illustrated in FIG. 8B, the intelligent re-driver 810 can be packaged together with optics 820 and implemented as an intermediary between the processing unit 830 and an optical connector 860. In the NPO setting, re-drivers may also be connected to processing units through the copper interconnect 840 and connected to the optical connector 860 through the fiber interconnect 850.

In the embodiment illustrated in FIG. 8C, where a CPO solution is implemented using intelligent re-drivers, the intelligent re-driver 810 and optics 820 are implemented together with the processing unit 830 and can be coupled to the optical connector 860 directly through the fiber interconnect 850.

While specific implementations of intelligent re-drivers as solutions in communication systems in accordance with various embodiments of the invention are described above with reference to FIGS. 8A-8C, re-drivers can be implemented using any of a variety of different configurations including alternative and/or additional components as solutions in communication systems as appropriate to the requirements of specific applications in accordance with various embodiments of the invention.

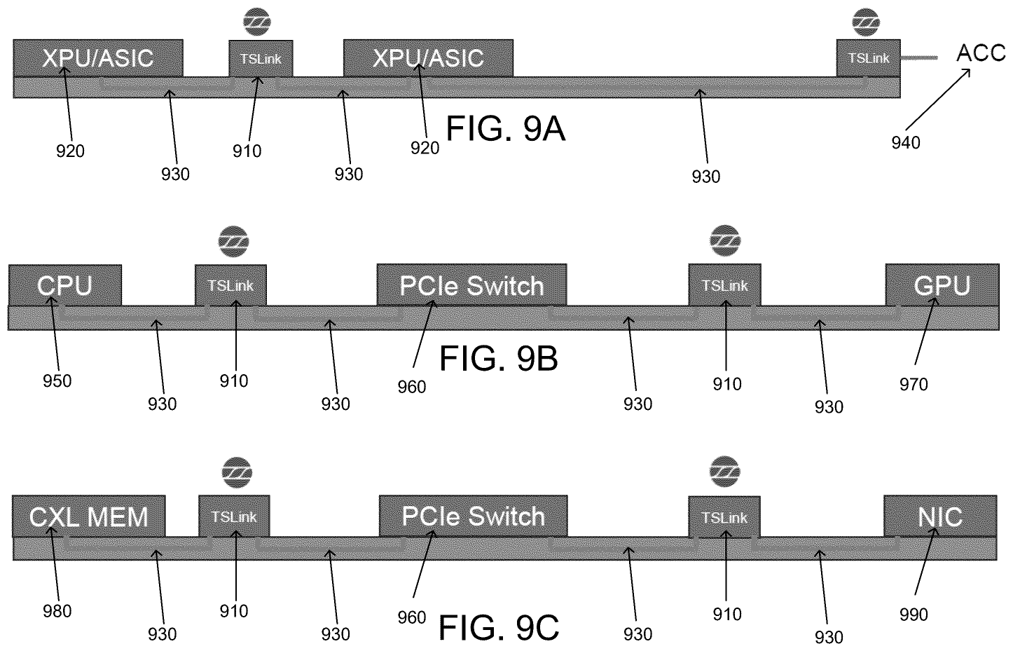

Intelligent re-drivers may also be implemented in copper interconnects. Implementations of intelligent re-drivers in copper interconnects in accordance with embodiments of the invention are illustrated in FIGS. 9A-9C. As illustrated in FIG. 9A, an intelligent re-driver 910 can be implemented to connect between processing units 920 through copper interconnects 930 and connected to an active copper cable (ACC) 940.

In the example illustrated in FIG. 9B, an intelligent re-driver 910 can be implemented between a central processing unit (CPU) 950 and a PCIe Switch 960 via copper interconnects 930. The PCIe switch 960 may connect to a GPU 970 via the intelligent re-driver 910 and copper interconnects 930.

In the embodiment illustrated in FIG. 9C, the intelligent re-driver 910 can be connected between a compute express link memory module (CXL MEM) 980 and a PCIe Switch 960 through copper interconnects 930. The PCIe Switch 960 may be connected to a network interface controller (NIC) through the intelligent re-driver 910 and copper interconnects 930.

While specific implementations of intelligent re-drivers in copper interconnects in accordance with various embodiments of the invention are described above with reference to FIGS. 9A-9C, re-drivers can be implemented using any of a variety of different configurations including alternative and/or additional components in copper interconnects as appropriate to the requirements of specific applications in accordance with various embodiments of the invention.

Although specific methods of low latency communication using intelligent re-drivers are discussed above, many different methods of communication using re-drivers that provide an analog signal path and possess the ability to perform digital link adaptation can be implemented in accordance with various embodiments of the invention. For example, one of ordinary skill in the art will appreciate that methods of communication described above can be implemented in a variety of computing and/or networking applications. Furthermore, the documents filed herewith provide disclosure with respect to re-drivers implemented in accordance with specific embodiments of the invention and the disclosures of these documents hereby incorporated by reference herein in their entirety. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A re-driver comprising:
a programmable linear equalizer capable of equalizing a transmitted analog signal to generate an equalized signal;
a variable gain amplifier capable of amplifying the equalized signal to produce an amplified signal;
a line driver capable of generating an output signal based upon the amplified signal; and
digital link adaptation circuitry capable of:
sampling the amplified signal to produce a sampled signal;
generating programming parameters for the programmable linear equalizer based upon the sampled signal; and
programming the programmable linear equalizer.

2. The re-driver of claim 1, wherein:
the variable gain amplifier is a programmable variable gain amplifier; and
the digital link adaptation circuitry is further capable of:
generating programming parameters for the programmable variable gain amplifier based upon the sampled signal; and
programming the programmable variable gain amplifier.

3. The re-driver of claim 1, wherein the digital link adaptation circuitry is further capable of:
generating programming parameters for a transmitter based upon the sampled signal; and
sending the programming parameters to the transmitter.

4. The re-driver of claim 3, wherein the digital link adaptation circuitry is further capable of measuring a channel impulse response when the transmitted analog signal is a pulse.

5. The re-driver of claim 4, wherein the digital link adaptation circuitry is further capable of characterizing the channel by taking the derivative of the measured channel impulse response.

6. The re-driver of claim 5, wherein the duration of the pulse is greater than a time required for transients caused by reflections of the pulse within the channel to have settled.

7. The re-driver of claim 5, wherein the programming parameters for the transmitter are based upon the characterization of the channel.

8. The re-driver of claim 7, wherein the transmitter comprises a feed-forward equalizer (FFE) having a plurality of taps and the programming parameters configure the taps of the FFE.

9. The re-driver of claim 8, wherein:
the duration of the pulse is greater than a time required for transients caused by reflections of the pulse within the channel to have settled; and
the number of the plurality of taps of the FFE corresponds to a duration of time that is equal to or greater than the time required for transients caused by reflections of the pulse within the channel to have settled.

10. The re-driver of claim 1, wherein the programmable linear equalizer, the variable gain amplifier, the line driver, and the digital link adaptation circuitry are formed on a single integrated circuit.

11. The re-driver of claim 1, wherein the digital link adaptation circuitry comprises:
an analog to digital converter; and
a microcontroller unit (MCU).

12. The re-driver of claim 11, wherein:
the programmable linear equalizer, the variable gain amplifier, and the line driver are formed on a first integrated circuit; and
at least one of the analog to digital converter and the MCU are formed on a second integrated circuit capable of receiving signals from the first integrated circuit.

13. The re-driver of claim 11, wherein the analog to digital converter is a 12-bit analog to digital converter.

14. The re-driver of claim 11, wherein digital link adaptation circuitry is further capable of recovering a sampling clock signal from the sampled signal.

15. The re-driver of claim 14, wherein the digital link adaptation circuitry comprises:
a clock recovery unit configured to receive the sampled signal;
a phase interpolator configured to receive an input signal from the clock recovery unit; and
a clock divider configured to receive an input from the phase interpolator and output the sampling clock signal.

16. The re-driver of claim 15, wherein:
the clock recovery unit comprises:
a voltage controlled oscillator (VCO);
a phase lock loop (PLL); and
control circuitry comprising a control register, where the control circuitry is configured to control the control register based upon at least control signals received from the MCU;
the MCU is configured to receive the sampling clock signal from the clock divider and output control signals that are provided to the clock recovery unit, where the control signals are capable of being used by the clock recovery unit to control the frequency of the VCO.

17. The re-driver of claim 16, wherein the phase lock loop comprises:
a phase detector; and
a filter.

18. The re-driver of claim 17, wherein:
the MCU is connected to a crystal oscillator capable of generating a clock signal; and
the MCU is configured to:
obtain a reference signal using the clock signal; and
control the frequency of the VCO based upon the reference signal.

19. The re-driver of claim 1, wherein the digital link adaptation circuitry is further capable of receiving, via an input, a sampling clock signal from a synchronous clock source or a synchronous neighboring channel.

20. The re-driver of claim 1, wherein digital link adaptation circuitry is configurable to obtain a sampling clock signal by:
recovering the sampling clock signal from the sampled signal; or
receiving, via an input, the sampling clock signal from a synchronous clock source or a synchronous neighboring channel.

21. The re-driver of claim 1, further comprising a skew adjustor.

22. The re-driver of claim 1, further comprising a content management interoperability services (CMIS) interface capable of facilitating communication for link training.

23. The re-driver of claim 3, wherein the digital link adaptation circuitry sets feed-forward equalization coefficients for the transmitter of the re-driver.

24. The re-driver of claim 1, further comprising outputting digital eye diagram from the digital link adaptation circuitry to a digital eye monitor.

25. The re-driver of claim 1, wherein the digital link adaptation circuitry comprises a 12-bit analog-to-digital converter.

26. The re-driver of claim 1, wherein the programming parameters removes inter-symbol interference in a communication channel.

27. A method for performing link training of a high speed serial link, the method comprising:
sampling, at an extension device, an analog signal transmitted by a transmitter via a channel using an analog-to-digital converter, where the transmitted analog signal is a pulse;
characterizing, at the extension device, the channel based upon the sampled analog signal;
generating, at the extension device, parameters that are capable of being used by the transmitter to program an equalizer; and
transmitting, by the extension device, the generated parameters to the transmitter.

28. The method of claim 27, wherein the duration of the pulse is greater than a time required for transients caused by reflections of the pulse within the channel to have settled.

29. The method of claim 28, further comprising:
measuring a channel impulse response based upon the sampled analog signal;
and
characterizing the channel based upon the sampled analog signal comprises taking a derivative of the measured channel impulse response.

30. The method of claim 29, wherein the generated parameters are capable of being used by the transmitter to program an equalizer that is a Feed Forward Equalizer (FFE) having a plurality of taps, where the number of the plurality of taps of the FFE corresponds to a duration of time that is equal to or greater than the time required for transients caused by reflections of the pulse within the channel to have settled.

31. The method of claim 27, wherein:
the extension device is a re-driver comprising a programmable linear equalizer; and
the method further comprises:
generating programming parameters for the programmable linear equalizer based upon the sampled analog signal; and
programming the programmable linear equalizer based upon the generated programming parameters.

32. The method of claim 28, wherein the extension device is a re-timer.

33. A re-driver capable of receiving a transmitted analog signal via a channel comprising:
a programmable linear equalizer capable of equalizing the transmitted analog signal to generate an equalized signal;
a variable gain amplifier capable of amplifying the equalized signal to produce an amplified signal, wherein the variable gain amplifier is a programmable variable gain amplifier;
a line driver capable of generating an output signal based upon the amplified signal; and
digital link adaptation circuitry comprising:
an analog to digital converter; and
a microcontroller unit (MCU);
wherein the digital link adaptation circuitry is capable of:
sampling the amplified signal to produce a sampled signal when the transmitted analog signal is a pulse;
measuring a channel impulse response;
characterizing the channel by taking the derivative of the measured channel impulse response having a duration that is greater than a time required for transients caused by reflections of the pulse within the channel to have settled;
generating programming parameters for the programmable linear equalizer based upon the characterization of the channel;
programming the programmable linear equalizer using the programming parameters for the programmable linear equalizer;
generating programming parameters for the programmable variable gain amplifier based upon the characterization of the channel;
programming the programmable variable gain amplifier using the programming parameters for the programmable variable gain amplifier;
generating programming parameters for a transmitter that are capable of being used by the transmitter to program a plurality of taps of a feed forward equalizer based upon the characterization of the channel; and
transmitting the programming parameters for the transmitter to the transmitter;
wherein the programmable linear equalizer, the variable gain amplifier, and the line driver are formed on a first integrated circuit;
wherein at least one of the analog to digital converter and the MCU are formed on a second integrated circuit capable of receiving signals from the first integrated circuit; and
wherein the MCU is configured to receive a clock signal from a crystal oscillator.

34. The re-driver of claim 33, wherein the digital link adaptation circuitry comprises:
a clock recovery unit configured to receive the sampled signal, where the clock recovery unit further comprises:
a voltage controlled oscillator (VCO);
a phase lock loop (PLL); and
control circuitry comprising a control register, where the control circuitry is configured to control the control register based upon at least control signals received from the MCU;
a phase interpolator configured to receive an input signal from the clock recovery unit; and
a clock divider configured to receive an input from the phase interpolator and output the sampling clock signal;
wherein the MCU is configured to receive the sampling clock signal from the clock divider and output control signals that are provided to the clock recovery unit, where the control signals are capable of being used by the clock recovery unit to control the frequency of the VCO; and
wherein the MCU is configured to:
obtain a reference signal using the clock signal; and
control the frequency of the VCO based upon the reference signal.

35. The re-driver of claim 33, wherein the channel is an optical communication channel.
